(19) United States
(12) Patent Application Publication
(10) Pub. No.: US 2024/0251518 A1
(43) Pub. Date: Jul. 25, 2024

(54) ELECTRONIC APPARATUS INCLUDING DISPLAY PROTECTIVE MEMBER

(71) Applicant: Samsung Electronics Co., Ltd., Suwon-si (KR)

(72) Inventors: Youngkyong JO, Suwon-si (KR); Seokki KIM, Suwon-si (KR); Bora LEE, Suwon-si (KR); Sangbong LEE, Suwon-si (KR); Jongsu LEE, Suwon-si (KR); Seongwoo CHOI, Suwon-si (KR)

(21) Appl. No.: 18/624,451

(22) Filed: Apr. 2, 2024

Related U.S. Application Data
(63) Continuation of application No. PCT/KR2022/015045, filed on Oct. 6, 2022.

(30) Foreign Application Priority Data
Oct. 6, 2021 (KR) 10-2021-0132580
Oct. 6, 2022 (KR) 10-2022-0127872

(51) Int. Cl. H05K 5/03; H05K 5/02

(52) U.S. Cl. CPC H05K 5/03; H05K 5/0226

(57) ABSTRACT

A foldable electronic device is provided. The foldable electronic device includes a foldable housing including multiple housings and at least one hinge configured to rotatably couple the multiple housings, the folding housing being folded around the hinge, and a flexible display disposed on the foldable housing so as to be folded according to a folding operation of the foldable housing, wherein the flexible display includes a panel layer configured to display image information, a glass layer positioned above the panel layer with reference to a direction in which the image information is displayed, the glass layer being folded when the flexible display is folded, a folding region positioned on a folding part of the glass layer, the folding region including multiple through-holes formed to penetrate the glass layer in the thickness direction and arranged regularly on a surface of the glass layer, and a rib, which is a region between the multiple through-holes adjacent to each other, a flexible polymer region including a transparent and elastic flexible polymer material positioned in the through-holes, and a hard coating layer positioned on upper surfaces of the glass layer and the flexible polymer region, the hard coating layer having a higher elastic modulus than the transparent and elastic flexible polymer material.

### CROSS-REFERENCE TO RELATED APPLICATION(S)

This application is a continuation application, claiming priority under §365(c), of an International application No. PCT/KR2022/015045, filed on Oct. 6, 2022, which is based on and claims the benefit of a Korean patent application number 10-2021-0132580, filed on Oct. 6, 2021, in the Korean Intellectual Property Office, and of a Korean patent application number 10-2022-0127872, filed on Oct. 6, 2022, in the Korean Intellectual Property Office, the disclosure of each of which is incorporated by reference herein in its entirety.

### BACKGROUND

### 1. Field

The disclosure relates to an electronic device. More particularly, the disclosure relates to an electronic device including a display protection member.

### 2. Description of Related Art

Electronic devices need a small profile for portability, and need a large display area in order to provide users with a large amount of information. In order to have both a small profile and a large display area, electronic devices have evolved from existing form factors (rectangular bar shapes) into various form factors (rollable, slidable, or foldable). An electronic device having a foldable form factor needs a flexible display capable of bending or folding.

The display of an electronic device may include a protection layer configured to prevent foreign materials from infiltrating from above a panel layer, thereby protecting the panel layer. A flexible display used for an electronic device having a rollable, slidable, or foldable form factor needs a flexible protection layer capable of bending or folding together with the display panel. The protection layer may include a flexible layer such as transparent polyimide or ultrathin glass, for example.

The above information is presented as background information only to assist with an understanding of the disclosure. No determination has been made, and no assertion is made, as to whether any of the above might be applicable as prior art with regard to the disclosure.

### SUMMAR

If a panel side protection member including a joint portion is used during a bending operation of a flexible display, the panel side and the protection member may be moved away from each other by the bending operation, and foreign materials (for example, sand and dust) may then infiltrate the panel side from the outside, thereby damaging the panel. In addition, the panel side protection member including a joint portion having complicated maneuverability is assembled to the side of the flexible display through a separate assembly process, and this may increase the complexity of the electronic device manufacturing process.

Aspects of the disclosure are to address at least the above-mentioned problems and/or disadvantages and to provide at least the advantages described below. Accordingly, an aspect of the disclosure is to provide a display side protection member and an electronic device including the same, wherein the display side protection member prevents foreign materials from infiltrating the side surface of a flexible display and is applicable to the side surface of the flexible display through a simple process.

Additional aspects will be set forth in part in the description which follows and, in part, will be apparent from the description, or may be learned by practice of the presented embodiments.

In accordance with an aspect of the disclosure, a foldable electronic device is provided. The foldable electronic device includes a foldable housing including multiple housings and at least one hinge configured to rotatably couple the multiple housings, the folding housing being folded around the hinge, and a flexible display disposed on the foldable housing so as to be folded according to a folding operation of the foldable housing. The flexible display includes a panel layer configured to display image information, a glass layer positioned above the panel layer with reference to a direction in which the image information is displayed, the glass layer being folded when the flexible display is folded, a folding region positioned on a folding part of the glass layer, the folding region including multiple through-holes formed to penetrate the glass layer in a thickness direction and arranged regularly on a surface of the glass layer, and a rib which is a region between the multiple through-holes adjacent to each other, a flexible polymer region including a transparent and elastic flexible polymer material positioned in the through-holes, and a hard coating layer positioned on upper surfaces of the glass layer and the flexible polymer region, the hard coating layer having a higher elastic modulus than the transparent and elastic flexible polymer material.

In some embodiments, the flexible polymer material may have an elastic modulus of 1 to 1000 kPa. In some embodiments, the hard coating layer may have an elastic modulus of 1 to 10 Gpa.

In some embodiments, the foldable electronic device includes a hardness transition layer positioned below the hard coating layer and above the glass layer, the hardness transition layer including a medium-hardness polymer material having an elastic modulus higher than the flexible polymer material and lower than the hard coating layer. In some embodiments, the hardness transition layer includes a first hardness transition layer including a material having the same elastic modulus as the flexible polymer material, and a second hardness transition layer including the medium-hardness polymer material.

In some embodiments, the foldable electronic device includes a repulsive force absorption layer positioned below the glass layer. In some embodiments, the material of the repulsive force absorption layer may have the same elastic modulus as the flexible polymer material. In some embodiments, the repulsive force absorption layer includes a first repulsive force absorption layer and a second repulsive force absorption layer having a higher elastic modulus than the first repulsive force absorption layer.

In some embodiments, the through-holes includes slit shapes extending in a direction parallel to a folding axis of the foldable electronic device. In some embodiments, the through-holes includes wave shapes which extend in a direction parallel to the folding axis of the foldable electronic device, and which are bent in a direction perpendicular to the folding axis on a surface of the glass layer.

In some embodiments, the through-holes includes rhombus shapes on a surface of the glass layer. In other embodiments, the folding region includes a rib which is a region between the multiple through-holes adjacent to each other, and the rib includes a wave shape bent in a direction perpendicular to the folding axis on a surface of the glass layer.

In some embodiments, the through-holes includes taper shapes such that the width of the through-holes changes gradually along the thickness direction of the glass layer.

In some embodiments, the folding region includes a first folding region which is a region adjacent to a folding axis of the foldable electronic device, and a second folding region positioned on a peripheral portion of the first folding region around the folding axis of the foldable electronic device, and when the foldable electronic device is folded, the radius of curvature of the first folding region may be larger than the radius of curvature of the second folding region. In some embodiments, the width of at least one of the through-holes or the rib in the first folding region may be small compared with the second folding region.

In other embodiments, the folding region includes a first folding region which is a region adjacent to a folding axis of the foldable electronic device, and a second folding region positioned on a peripheral portion of the first folding region around the folding axis of the foldable electronic device. The first folding region may be folded in, when the foldable electronic device is folded, such that the upper end portion of the glass layer is positioned inside a curved shape formed by folding of the first folding region. The second folding region may be folded out such that the upper end portion of the glass layer is positioned outside a curved shape formed in the second folding region. In some embodiments, the width of at least one of the through-holes or the rib in the first folding region may be small compared with the second folding region. In some embodiments, the through-holes includes a taper such that the width of the through-holes changes gradually along the thickness direction of the glass layer, and the through-holes in the first folding region and the second folding region may have tapers in opposite directions.

In some embodiments, the foldable housing includes a first housing, a second housing, a third housing, a first hinge portion configured to foldably connect the first housing and the second housing, and a second hinge portion configured to foldably connect the second housing and the third housing. The folding region includes a first folding region positioned in a region of the glass layer corresponding to the first hinge portion, and a second folding region positioned in a region of the glass layer corresponding to the second hinge portion. The first folding region may be folded in, when the foldable electronic device is folded, such that the upper end portion of the glass layer is positioned inside a curved shape formed by folding of the first folding region. The second folding region may be folded out such that the upper end portion of the glass layer is positioned outside a curved shape formed in the second folding region.

In other embodiments, the foldable housing includes a first housing, a second housing, a third housing, a first hinge portion configured to foldably connect the first housing and the second housing, and a second hinge portion configured to foldably connect the second housing and the third housing. The folding region includes a first folding region positioned in a region of the glass layer corresponding to the first hinge portion, and a second folding region positioned in a region of the glass layer corresponding to the second hinge portion. When the foldable electronic device is folded, the radius of curvature of the second folding region may be larger than the radius of curvature of the first folding region, and the first housing may be folded to be positioned between the second housing and the third housing.

In accordance with another aspect of the disclosure, a display protection member of a foldable electronic device is provided. The display protection member includes a folding region including multiple through-holes arranged regularly on the surface of a glass layer such that the display protection member bends together during a bending operation of a flexible display, thereby preventing foreign materials from infiltrating the surface of the flexible display and protecting the flexible display from external stress.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device inside a network environment according to an embodiment of the disclosure;

FIGS. 2A, 2B, 2C, 2D, 2E, and 2F illustrate a portable electronic device having an infolding-type housing structure according to various embodiments of the disclosure;

FIG. 3A is front and side views of a display protection member of a foldable electronic device according to an embodiment of the disclosure;

FIG. 3B is a rear view of a display protection member according to an embodiment of the disclosure;

FIG. 3C is a sectional view of a display protection member according to an embodiment of the disclosure;

FIG. 4A is a side view of a folding operation of a display protection member according to an embodiment of the disclosure;

FIG. 4B is a side view of a folding operation of a display protection member according to an embodiment of the disclosure;

FIG. 5A is a sectional view of a display protection member according to an embodiment of the disclosure;

FIG. 5B is a sectional view of a display protection member according to an embodiment of the disclosure;

FIGS. 5C, 5D, and 5E are sectional views of a display protection member according to various embodiments of the disclosure;

FIG. 5F is a sectional view of a display protection member according to an embodiment of the disclosure;

FIGS. 6A, 6B, 6C, and 6D are magnified plan views illustrating the shape of through-holes according to various embodiments of the disclosure;

FIG. 7A is a plan view of a foldable electronic device according to an embodiment of the disclosure;

FIG. 7B is a side sectional view of a display protection member of a foldable electronic device according to an embodiment of the disclosure;

FIG. 7C is a magnified sectional view of a hinge portion of a foldable electronic device according to an embodiment of the disclosure;

FIG. 8A is a plan view illustrating a foldable electronic device in an unfolded state and in a folded state according to an embodiment of the disclosure;

FIG. 8B is a side view of a foldable electronic device in a folded state according to an embodiment of the disclosure;

FIG. 8C is a side view of a foldable electronic device in a folded state according to an embodiment of the disclosure;

FIG. 9 is a perspective view of a test device for first evaluation, second evaluation, and third evaluation, together with a view of the test device according to an embodiment of the disclosure;

FIG. 10 is a graph illustrating the minimum surface compressive stress which a first layer is to have so as to cause substantially no damage to the first layer, in terms of the fall height of a pen input device, according to an embodiment of the disclosure;

FIG. 11 is a graph illustrating the fall height of a pen input device at which the first layer is damaged, in terms of the thickness of the first layer, as first evaluation of a laminate including the first layer in FIGS. 3A to 3C, according to an embodiment of the disclosure;

FIG. 12 illustrates a test device and a first layer in relation to first evaluation, and a test device and a first layer in relation to second evaluation, according to an embodiment of the disclosure;

FIG. 13 is a graph illustrating the fall height of a pen input device at which a first layer is damaged, in terms of the thickness of the first layer, as a result of first evaluation through a test device, and illustrating the pressurization load through a pen input device by which the first layer is damaged, in terms of the thickness of the first layer, as a result of second evaluation through the test device according to an embodiment of the disclosure;

FIG. 14 is a graph illustrating a fracture load in terms of the thickness of a first layer as the result of third evaluation through a test device according to an embodiment of the disclosure; and

FIG. 15 is a sectional view of a first layer in a folded state of an electronic device, together with a graph illustrating the minimum radius of curvature at which the first layer may bend without fracture, in terms of the thickness of the first layer according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory or the one or more computer programs may be divided with different portions stored in different multiple memories.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an integrated circuit (IC), or the like.

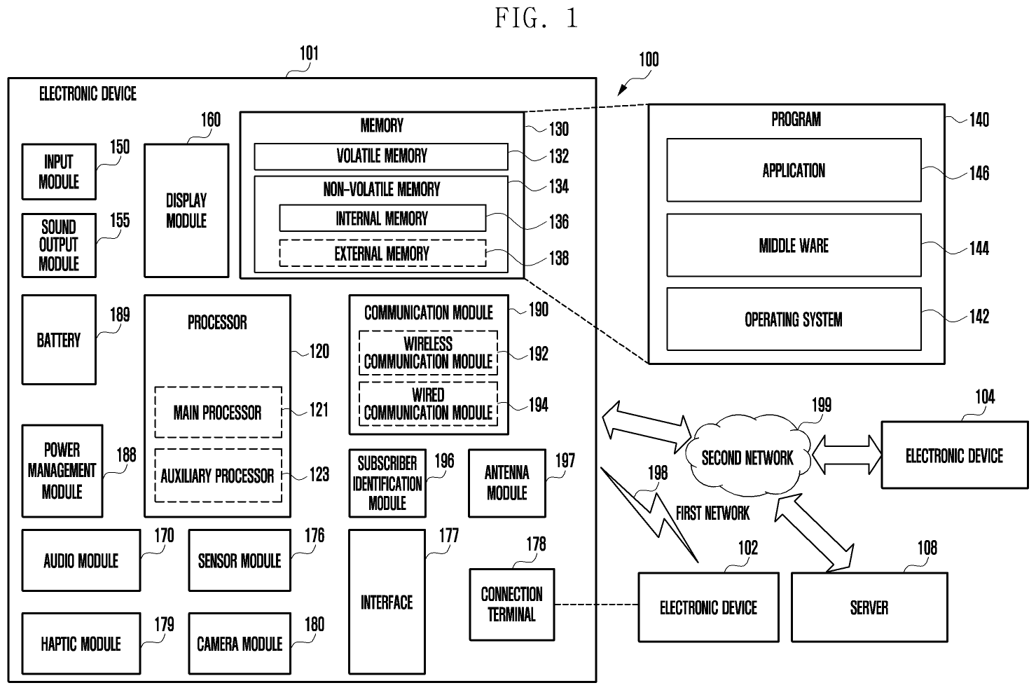

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input 1 module 150, a sound output 1 module 155, a display 1 module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display 1 module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input 1 module 150 may receive a command or data to be used by another component (e.g., the processor 120) of the electronic device 101, from the outside (e.g., a user) of the electronic device 101. The input 1 module 150 may include, for example, a microphone, a mouse, a keyboard, a key (e.g., a button), or a digital pen (e.g., a stylus pen).

The sound output 1 module 155 may output sound signals to the outside of the electronic device 101. The sound output 1 module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display 1 module 160 may visually provide information to the outside (e.g., a user) of the electronic device 101. The display 1 module 160 may include, for example, a display, a hologram device, or a projector and control circuitry to control a corresponding one of the display, hologram device, and projector. According to an embodiment, the display 1 module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input 1 module 150, or output the sound via the sound output 1 module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 gigabits per second (Gbps) or more) for implementing eMBB, loss coverage (e.g., 164 decibels (dB) or less) for implementing mMTC, or U-plane latency (e.g., 0.5 milliseconds (ms) or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

According to various embodiment, a portable electronic device (for example, the electronic device 101 in FIG. 1) may have a foldable housing divided into two housings with reference to a folding axis. The first portion of a display (for example, a flexible display) may be disposed on the first housing, and the second portion of the display may be disposed on the second housing. The foldable housing may be implemented in an infolding type such that, when the portable electronic device is folded, the first and second portions face each other. Alternatively, the foldable housing may be implemented in an outfolding type such that, when the portable electronic device is folded, the first and second portions face in opposite directions. The surface on which the first and second portions of the display are disposed may be defined as the front surface of the portable electronic device, the opposite surface thereof may be defined as the rear surface of the portable electronic device, and the surface surrounding the space between the front and rear surfaces may be defined as the side surface of the portable electronic device.

According to an embodiment mentioned herein, a case of infolding in which the first portion of the display is disposed on the first housing so as to face the second portion of the display disposed on the second housing when the display of the portable electronic device is folded is illustrated and described as an example, but the same may be identically applied to a case of outfolding in which the first portion of the display disposed on the first housing 210 and the second portion of the display disposed on the second housing face in opposite directions when the display is folded according to an embodiment. In addition, embodiments may also be applied to a multi-foldable electronic device which combines infolding and infolding, which combines infolding and outfolding, or which combines outfolding and outfolding.

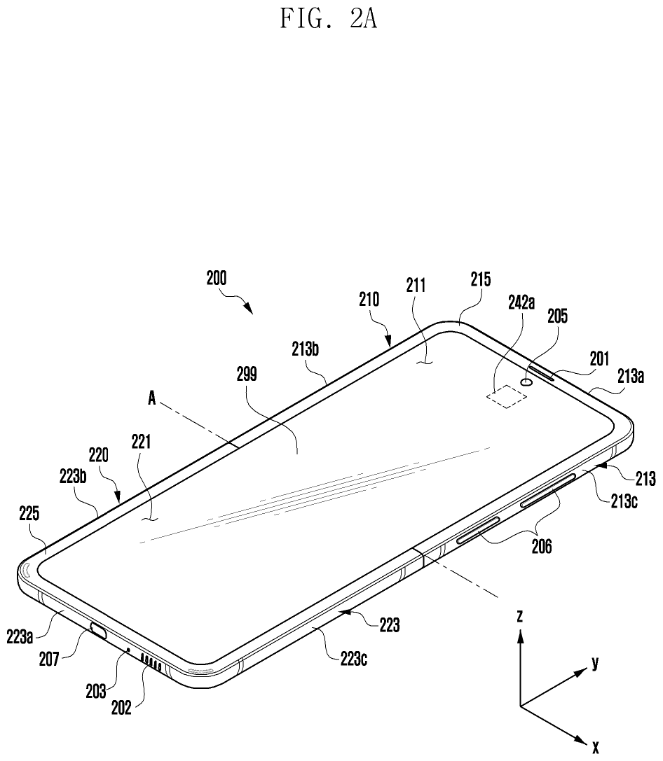

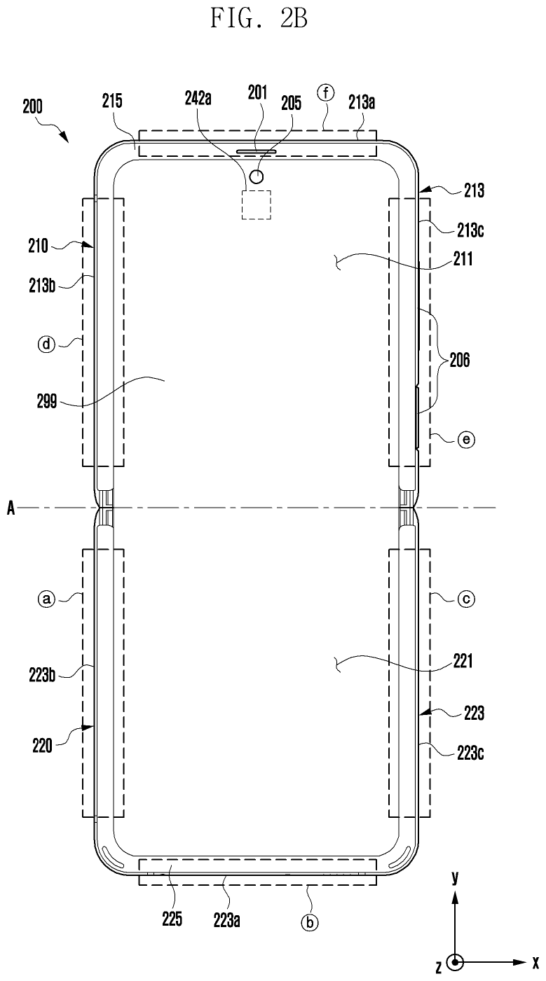

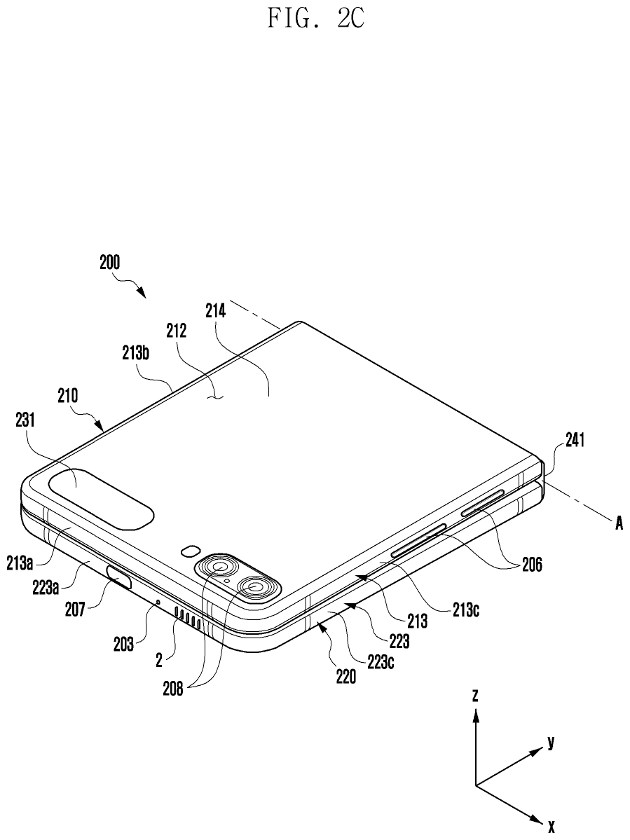

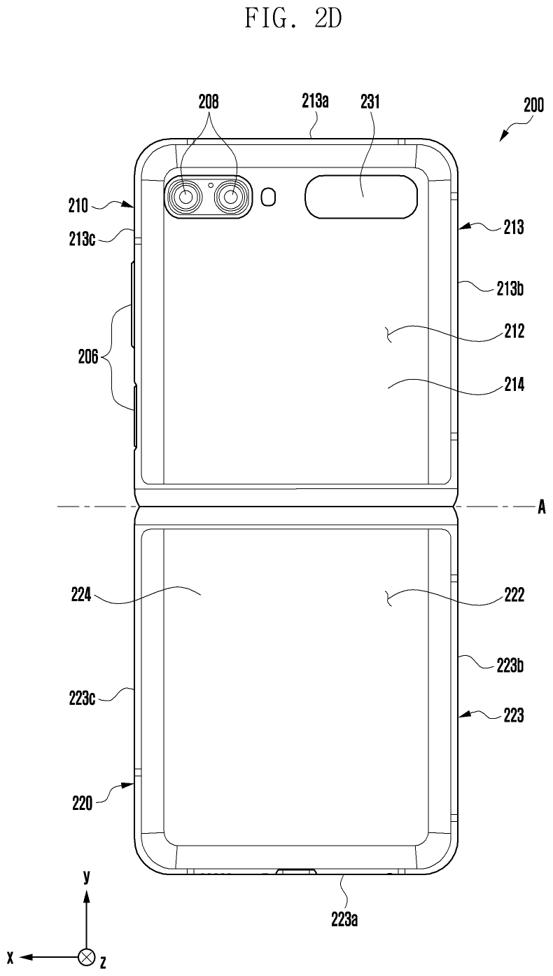

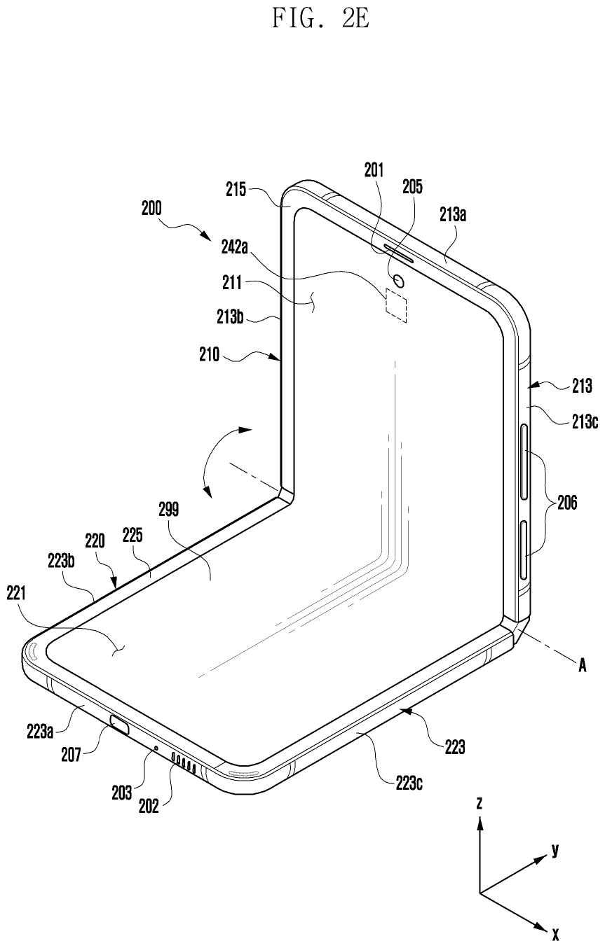

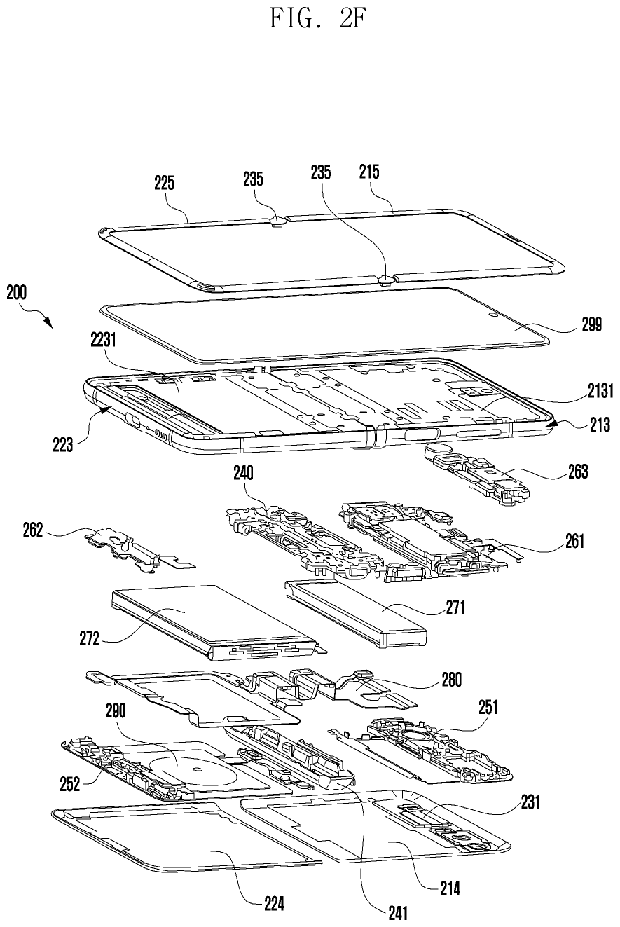

FIGS. 2A, 2B, 2C, 2D, 2E, and 2F illustrate a portable electronic device 200 having an infolding-type housing structure according to various embodiments of the disclosure. Specifically, FIGS. 2A and 2B are front views of a foldable portable electronic device (hereinafter, simply referred to as an electronic device) according to various embodiments in an unfolded, flat, or open state, FIG. 2C is a rear view of the electronic device in a folded or closed state, FIG. 2D is a rear view thereof in the unfolded state, FIG. 2E is a front view thereof in a partially folded state (in other words, in a partially unfolded state, or in an intermediate state (free-stop state) between a fully folded state and a fully unfolded state), and FIG. 2F is an exploded perspective view of the electronic device.

Referring to FIGS. 2A to 2F, the portable electronic device 200 (for example, the electronic device 101 in FIG. 1) may include a first housing 210, a second housing 220, a hinge assembly 240 configured to connect the first housing 210 and the second housing 220 such that the second housing 220 is rotatable with regard to the first housing 210, a flexible or foldable display 299 disposed in a space formed by the foldable housings 210 and 220, and a sensor module (for example, the sensor module 176 in FIG. 1).

The display 299 may be disposed from the first housing 210 to the second housing 220 across the hinge assembly 240. The display 299 may be divided into a first display region 211 disposed in the inner space of the first housing 210 with reference to a folding axis A, and a second display region 221 disposed in the inner space of the second housing 220. The sensor module (for example, an illuminance sensor) may be disposed below the sensor region (or light-transmitting region) 242a of the first display region 211 when seen from the front. The position and/or size of the sensor region 242a in the first display region 211 may be determined by the position and/or size of the illuminance sensor disposed below the same. For example, the size (for example, diameter) of the sensor region 242a may be determined based on the field of view (FOV) of the illuminance sensor. In an embodiment, the sensor region 242a may be configured to have a lower pixel density and/or a lower wiring density than the periphery thereof in order to improve the optical transmittance. In some embodiments, the display 299 may include a protection layer 298 which includes a transparent material, and which protects the panel layer from foreign materials and impacts from the outside.

The hinge assembly 240 may be implemented in an infolding type such that the two display regions 211 and 221 face each other during a state transition of the portable electronic device 200 from an unfolded state (for example, the state in FIG. 2A) to a folded state (for example, the state in FIG. 2C). For example, in the unfolded state of the electronic device 200, the two display regions 211 and 221 may face in substantially the same direction. The two display regions 211 and 221 may rotate in a direction so as to face each other in response to a state transition from the unfolded state to the folded state. The hinge assembly 240 may be configured to have resistance to rotations of the foldable housings 210 and 220. The foldable housings 210 and 220 may be rotated if an external force applied to the foldable housings 210 and 220 exceeds the resistance.

The state of the electronic device 200 may be defined based on the angle between the two display regions 211 and 221. For example, the state of the electronic device 200 may be defined as an unfolded, flat, or open state when the angle between the two display regions 211 and 221 is about 180°. The state of the portable electronic device 200 may be defined as a folded or closed state when the angle between the two display regions 211 and 221 is about 0-10°. When the two display regions 211 and 221 form an angle (for example, about 10-179°) larger than the angle in the folded state and smaller than the angle in the unfolded state, the state of the portable electronic device 200 may be defined as an intermediate state as illustrated in FIG. 2E (in other words, an a partially folded or partially unfolded state).

Based on the state of the portable electronic device 200, the active region in which visual information (for example, texts, images, or icons) is to be displayed on the display 299 may be determined. For example, it may be determined that, when the electronic device 200 is in the intermediate state, the first display region 211 or the second display region 221 is the active region. One of the first display region 211 and the second display region 221, which has less movements, may be determined as the active region. For example, assuming that the user holds one housing of the electronic device 200 by one hand and then opens the other housing by a finger (for example, thumb) of the same hand or by the other hand, the electronic device 200 undergoes a state transition from the folded state to the intermediate state, and the electronic device 200 may accordingly determine that the display region of the held housing (that is, the housing with less movements) is the active region. In the unfolded state of the portable electronic device 200, the entire region (for example, the first display region 211 and the second display region 221) of the display 299 may be determined as the active region.

According to various embodiments, the first housing 210 may include a first surface (first display region) 211 facing in a first direction (for example, forward direction) (z-axis direction) in the unfolded state, and a second surface 212 facing in a second direction (for example, rearward direction) (−z-axis direction) in which the same faces the first surface 211. The second housing 220 may include a third surface (second display region) 221 facing in the first direction (for example, z-axis direction) in the unfolded state, and a fourth surface 222 facing in the second direction (for example, −z-axis direction). The electronic device 200 may operate in such a manner that the first surface 211 of the first housing 210 and the third surface 221 of the second housing 220 face in the same first direction (for example, z-axis direction) in the unfolded state, and the first surface 211 and the third surface 221 face each other in the folded state. The electronic device 200 may operate in such a manner that the second surface 212 of the first housing 210 and the fourth surface 222 of the second housing 220 face in the same second direction (−z-axis direction) in the unfolded state, and the second surface 212 and the fourth surface 222 face in opposite directions in the folded state.

According to various embodiments, the first housing 210 may include a first side frame 213 configured to form the exterior of the electronic device 200 at least partially, and a first rear cover 214 coupled to the first side frame 213 and configured to form at least a part of the second surface 212 of the electronic device 200. According to an embodiment, the first side frame 213 may include a first side surface 213a, a second side surface 213b extending from one end of the first side surface 213a, and a third side surface 213c extending from the other end of the first side surface 213a. According to an embodiment, the first side frame 213 may be formed in a rectangular (for example, square or oblong) shape through the first side surface 213a, the second side surface 213b, and the third side surface 213c.

A part of the first side frame 213 may be made of a conductor. For example, referring to FIG. 2B, a part \textcircled{f} of the first side surface 213a, a part \textcircled{d} of the second side surface 213b, and a part \textcircled{e} of the third side surface 213c may be made of a metal material. The conductor may be electrically connected to a grip sensor (not illustrated) disposed adjacent thereto in the inner space of the first housing 210. A processor may measure the capacitance formed between the conductor and the ground (for example, the ground of a main printed circuit board) through the grip sensor and may recognize, based on the measured capacitance value, a dielectric object (for example, a finger, a palm, or a face) approaching (or contacting) the first housing 210 and the place at which the dielectric object contacts the first housing 210 (for example, the first side surface 213a, the second side surface 213b, or the third side surface 213c).

According to various embodiments, the second housing 220 may include a second side frame 223 configured to form the exterior of the electronic device 200 at least partially, and a second rear cover 224 coupled to the second side frame 223 and configured to form at least a part of the fourth surface 222 of the electronic device 200. According to an embodiment, the second side frame 223 may include a fourth side surface 223a, a fifth side surface 223b extending from one end of the fourth side surface 223a, and a sixth side surface 223c extending from the other end of the fourth side surface 223a. According to an embodiment, the second side frame 223 may be formed in a rectangular shape through the fourth side surface 223a, the fifth side surface 223b, and the sixth side surface 223c.

A part of the second side frame 223 may be made of a conductor. For example, referring to FIG. 2B, a part \textcircled{b} of the fourth side surface 223a, a part of the fifth side surface 223b, and a part \textcircled{c} of the sixth side surface 233c may be made of a metal material. The conductor may be electrically connected to a grip sensor (not illustrated) disposed adjacent thereto in the inner space of the second housing 220. The processor may measure the capacitance formed between the conductor and the ground (for example, the ground of the main printed circuit board) through the grip sensor and may recognize, based on the measured capacitance value, a dielectric object approaching (or contacting) the second housing 220 and the place at which the dielectric object contacts the second housing 220 (for example, the fourth side surface 223a, the fifth side surface 223b, or the sixth side surface 223c).

According to various embodiments, the pair of housings 210 and 220 is not limited to the illustrated form and coupling, and may be implemented by a combination and/or coupling of other shapes or components. For example, the first side frame 213 may be formed integrally with the first rear cover 214, and the second side frame 223 may be formed integrally with the second rear cover 224.

According to various embodiments, the first rear cover 214 and the second rear cover 224 may be formed by at least one of coted or colored glass, ceramic, polymer, or metal (for example, aluminum, stainless steel (STS), or magnesium), for example, or by a combination of at least two thereof.

According to various embodiments, the electronic device 200 may include a first protection cover 215 (for example, a first protection frame or a first decoration member) coupled along the periphery of the first housing 210. The electronic device 200 may include a second protection cover 225 (for example, a second protection frame or a second decoration member) coupled along the periphery of the second housing 220. According to an embodiment, the first protection cover 215 and the second protection cover 225 may be made of a metal or polymer material.

According to various embodiments, the electronic device 200 may include a sub-display 231 disposed separately from the display 299. According to an embodiment, the sub-display 231 may be disposed on the second surface 212 of the first housing 210 to be exposed at least partially such that, in a folded state, state information of the electronic device 200 may be displayed thereon. According to an embodiment, the sub-display 231 may be disposed to be visible from the outside through at least a partial region of the first rear cover 214. In some embodiments, the sub-display 231 may be disposed on the fourth surface 222 of the second housing 220. In such a case, the sub-display 231 may be disposed to be visible from the outside through at least a partial region of the second rear cover 224.

According to various embodiments, the electronic device 200 may include at least one of an input device 203, sound output devices 201 and 202, camera modules 205 and 208, a key input device 206, a connector port 207, and a sensor module (not illustrated). In an embodiment, the sensor module (for example, the sensor module 176 in FIG. 1) and the camera module 205 may be disposed below the display 299 when seen from the front.

According to various embodiments, the electronic device 200 may operate so as to maintain an intermediate state through the hinge assembly 240. In such a case, the electronic device 200 may control the display 299 such that the display region corresponding to the first surface 211 and the display region corresponding to the third surface 221 display different contents.

Referring to FIG. 2F, the electronic device 200 according to various embodiments may include a first side frame 213, a second side frame 223, and a hinge assembly 240 configured to rotatably connect the first side frame 213 and the second side frame 223. According to an embodiment, the electronic device 200 may include a first support plate 2131 extending at least partially from the first side frame 213 and a second support plate 2231 extending at least partially from the second side frame 223. According to an embodiment, the first support plate 2131 may be formed integrally with the first side frame 213 or structurally coupled to the first side frame 213. The second support plate 2231 may likewise be formed integrally with the second side frame 223 or structurally coupled to the second side frame 223. According to an embodiment, the electronic device 200 may include a display 299 disposed to be supported by the first support plate 2131 and the second support plate 2231. According to an embodiment, the electronic device 200 may include a first rear cover 214 coupled to the first side frame 213 so as to provide a first space between the same and the first support plate 2131, and a second rear cover 224 coupled to the second side frame 223 so as to provide a second space between the same and the second support plate 2231. In some embodiments, the first side frame 213 and the first rear cover 214 may be formed integrally. In some embodiments, the second side frame 223 and the second rear cover 224 may be formed integrally. According to an embodiment, the electronic device 200 may include a first housing 210 provided through the first side frame 213, the first support plate 2131, and the first rear cover 214. According to an embodiment, the electronic device 200 may include a second housing 220 provided through the second side frame 223, the second support plate 2231, and the second rear cover 224.

Although not illustrated, the hinge assembly 240 may include a first arm structure coupled to the first housing 210 (for example, the first support plate 2131), a second arm structure coupled to the second housing 220 (for example, the second support plate 2231), and a detent structure configured to physically contact the first arm structure and the second arm structure such that the first housing 210 and the second housing 220 have resistance to rotations. Contact forces exerted by the detent structure (for example, forces that push the first and second arm structures) may give the foldable housings 210 and 220 resistance to rotations.

According to various embodiments, the electronic device 200 may include a first board assembly 261 (for example, a main printed circuit board), a camera assembly 263, a first battery 271, or a first bracket 251 disposed in the first space between the first side frame (first side surface) 213 and the first rear cover 214.

According to an embodiment, the camera assembly 263 may include multiple cameras (for example, the camera modules 205 and 208 in FIGS. 2A and 2C), and may be electrically connected to the first board assembly 261. According to an embodiment, the first bracket 251 may provide improved rigidity and a support structure for supporting the first board assembly 261 and/or the camera assembly 263. According to various embodiments, the electronic device 200 may include a second board assembly 262 (for example, a sub-printed circuit board), an antenna 290 (for example, a coil member), a second battery 272, or a second bracket 252 disposed in the second space between the second side frame (second side surface) 223 and the second rear cover 224. According to an embodiment, the electronic device 200 may include a wiring member 280 (for example, a flexible printed circuit board (FPCB)) disposed to extend from the first board assembly 261 across the hinge assembly 240 to multiple electronic components (for example, the second board assembly 262, the second battery 272, or the antenna 290) disposed between the second side frame 223 and the second rear cover 224, thereby providing electric connection.

According to various embodiments, the electronic device 200 may include a hinge cover 241 configured to support the hinge assembly 240 and disposed such that, in a folded state of the electronic device 200, the hinge cover 241 is exposed to the outside and, in an unfolded state of the electronic device 200, the hinge cover 241 is moved into the first and second spaces and thus not visible from the outside.

According to various embodiments, the electronic device 200 may include a first protection cover 215 coupled along the periphery of the first side frame 213. According to an embodiment, the electronic device 200 may include a second protection cover 225 coupled along the periphery of the second side frame 223. In connection with the display 299, the periphery of the first display region 211 may be protected by the first protection cover 215. The periphery of the second display region 221 may be protected by the second protection cover 225. A protection cap 235 may be disposed in a region corresponding to the hinge assembly 240 so as to protect the bending part of the periphery of the display 299.

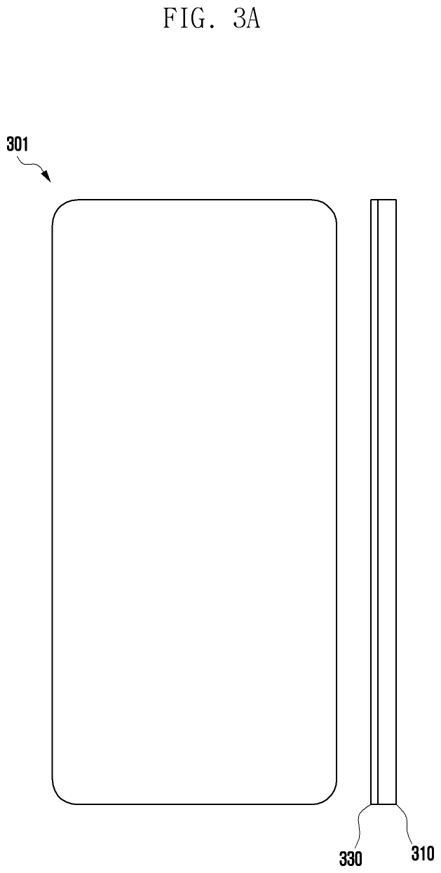

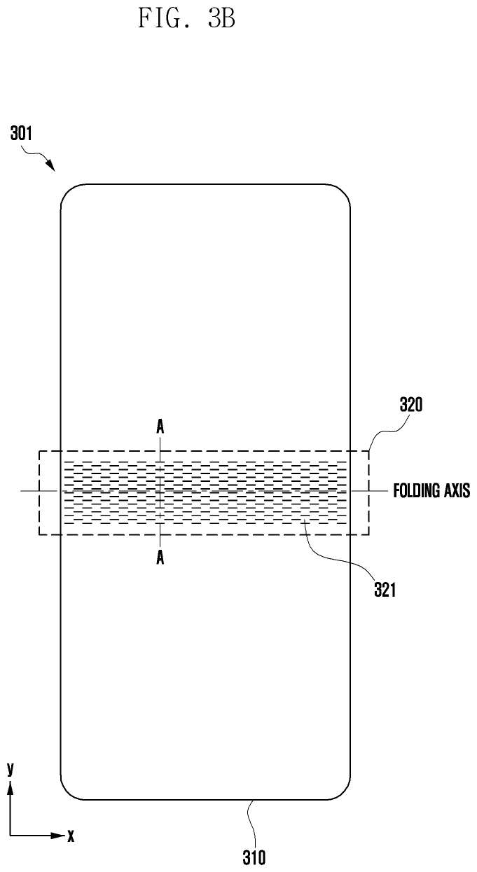

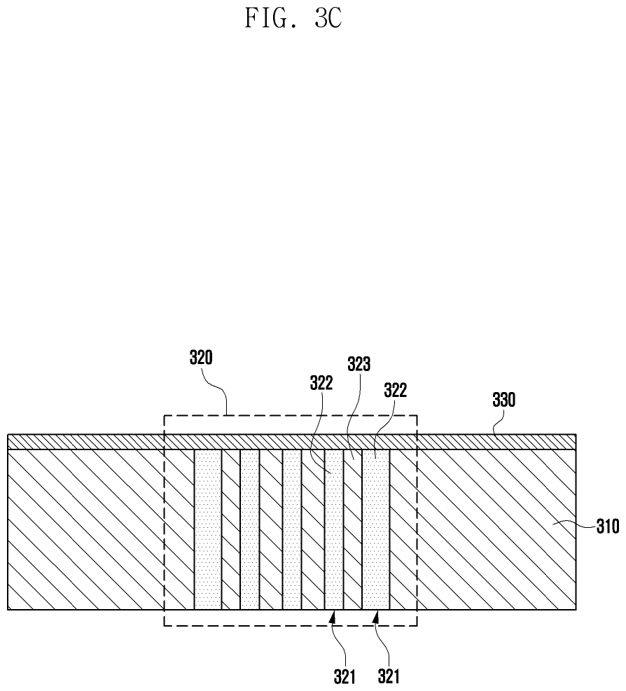

FIG. 3A is front and side views of a display protection member 301 of a foldable electronic device according to an embodiment of the disclosure.

FIG. 3B is a rear view of a display protection member 301 according to an embodiment of the disclosure.

FIG. 3C is a sectional view of a display protection member 301 according to an embodiment of the disclosure.

FIG. 3C is a sectional view taken along A-A in FIG. 3B.

Referring to FIG. 3A, the display protection member 301 (for example, the protection layer 298 in FIG. 2F) may include a glass layer 310 and a hard coating layer 330. The glass layer 310 may be positioned on the upper portion (hereinafter, terms such as “upper portion”, “lower portion”, above”, or “below” will be used with reference to the direction of the image display surface of the flexible display) of a component (for example, a panel, a polarization layer, and/or a color filter) of a flexible display (for example, the display 299 in FIGS. 2A to 2F) so as to protect the flexible display from foreign materials and impacts from the outside. The glass layer 310 may include a transparent and high-strength material, such as chemically strengthened glass, so as to transmit images displayed by the flexible display.

The glass layer 310 may substantially prevent the flexible display from being deformed by external pressures when an operation such as touch input or stylus input, for example, is performed. The glass layer 310 may have a sufficient thickness to accomplish structural rigidity capable of preventing deformation due to external pressures. For example, the glass layer 310 may have a thickness or 50 to 500 micrometers. The glass layer 310 may be folded around the folding axis in the folding region 320 (described later). The glass layer 310 may include multiple folding regions 320.

Referring to FIGS. 3B and 3C, the glass layer 310 may include a folding region 320 positioned on a part of the glass layer 310 bent during a folding operation of the foldable electronic device (for example, the electronic device 200 in FIGS. 2A to 2F). The folding region 320 may include multiple through-holes 321 which penetrate the glass layer 310 in the thickness direction, and which are arranged regularly on a surface of the glass layer 310. Regions of the glass layer 310 positioned between multiple through-holes 321 may be referred to as ribs 323. The number, shape, and arrangement of the through-holes 321 may change. Specific shapes of the through-holes 321 will be described later.

Referring to FIG. 3C, the display protection member 301 may include flexible polymer regions 322. The flexible polymer regions 322 may include flexible polymer materials which are positioned in the through-holes 321, and which have transparency and elasticity. The flexible polymer regions 322 may include flexible polymer materials having substantially the same refractive index as the glass layer 310 and filling the through-holes 321, thereby reducing distortion of images displayed on the flexible display due to reflection and refraction which would otherwise occur when light passes through inner surfaces of the through-holes 321. The flexible polymer regions 322 may include flexible polymer materials having high and low elastic moduli so as to elastically deform when the glass layer 310 is folded, thereby enabling a folding operation, as will be described later. The flexible polymer materials may include, for example, silicone, thermoplastic polyurethane (TPU), or polymethyl methacrylate (PMMA).

Referring to FIG. 3C, the display protection member 301 may include a hard coating layer 330 positioned on the upper portion of the glass layer 310.

The hard coating layer 330 may be positioned on the upper portion of the glass layer 310 so as to protect the glass layer 310 and the flexible polymer materials and to prevent the flexible polymer materials from being damaged or worn during a touch input or stylus input. The hard coating layer 330 may include a high-hardness material having higher hardness and/or elastic modulus than the flexible polymer materials of the flexible polymer regions 322. The high-hardness material may include a polymer material such as polycarbonate (PC), polysiloxane, or polyurethane acrylate, for example. In some embodiment, the hardness and/or elastic modulus of the high-hardness material may be adjusted by adjusting the ratio between hard and soft segments in the chains of the polymer material described above. In addition, the hardness and elastic modulus of the high-hardness material may be manufactured by adding a crosslinker that forms a crosslink between chains constituting the polymer described above, for example, a material such as trimethylolpropane (TMP) or epoxy crosslinker. In another embodiment, the hard coating layer 330 may be manufactured by forming an organic-inorganic hybrid coating layer from an organic precursor (for example, trimethoxysilane or titanium isopropoxide) of an inorganic material such as SiO2 or TiO2. The hard coating layer 330 may not only protect the flexible polymer regions 322, but also reduce or prevent any decrease in optical transmittance of the folding region 320 due to roughened surfaces of the flexible polymer regions 322. In some embodiments, the hard coating layer 330 may have an elastic modulus of 1 to 10 Gpa. If the hard coating layer 330 may has an elastic modulus of less than 1 Gpa, the coating may deform excessively, thereby failing to protect the glass layer 310 and the flexible polymer regions 322. If the hard coating layer 330 may has an elastic modulus exceeding 10 Gpa, the brittleness increases due to the excessively high hardness of the hard coating layer 330. Accordingly, the hard coating layer 330 may be damaged too easily, and the high elastic modulus may apply an excessively strong repulsive force against folding of the display protection member 301 and the foldable display as a whole.

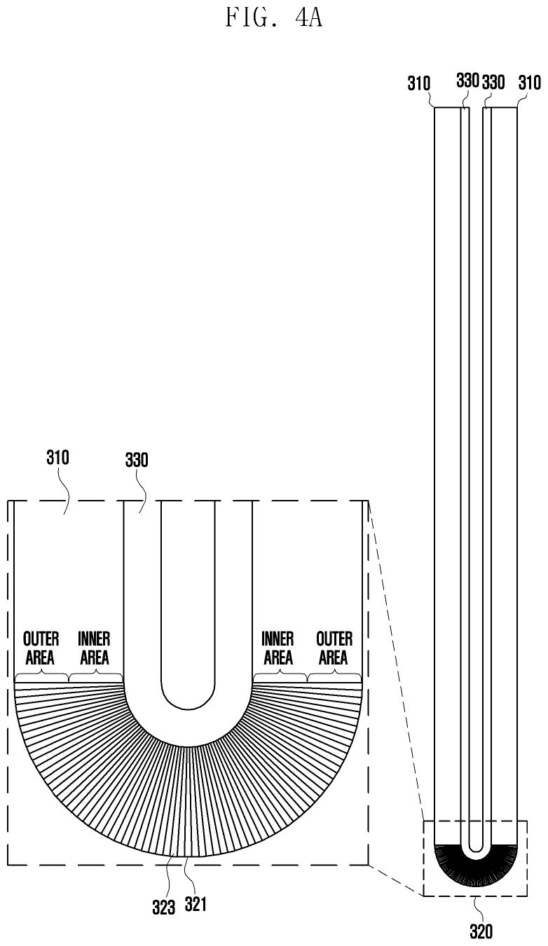

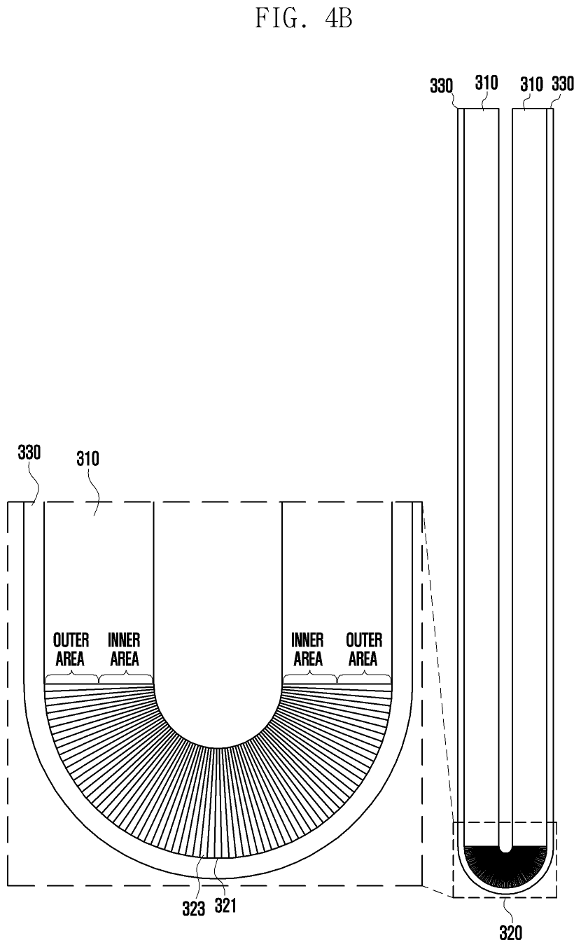

FIG. 4A is a side view of a folding operation of a display protection member 301 according to an embodiment of the disclosure.

FIG. 4B is a side view of a folding operation of a display protection member 301 according to an embodiment of the disclosure.

Referring to FIGS. 4A and 4B, the display protection member 301 according to embodiments of the disclosure may be bent around a folding region 320. Referring to FIG. 4A, in some embodiments, the display protection member 301 may be folded in an infolding type such that, with reference to the direction in which the flexible display displays images, the upper end portion thereof is positioned on the inside of the curved surface. Referring to FIG. 4B, in another embodiment, the display protection member 301 may be folded in an outfolding type such that the upper end portion thereof is positioned on the outside of the curved surface.

The folding region 320 may elastically deform when the display protection member 301 is folded, and the shape of the through-hole 321 may thus be changed. The width A1 of the through-holes 321 may decrease as the ribs 323 are deformed by a compressive stress in the inner area with reference to the state in which the display protection member 301 is folded, and the width A2 of the through-holes 321 may increase as the ribs 323 are deformed by a tensile stress in the outer area. Deformation of the through-holes 321 may change the shape of flexible polymers filling the inside of the through-holes 321. Due to the existence of the through-holes 321 and the elastic deformation of the flexible polymers filling the inside of the through-holes 321, the glass layer 310 may be folded together with the flexible display. That is, the glass layer 310 may have both a sufficient thickness to accomplish structural rigidity for preventing deformation due to external pressures and flexibility that enables the same to be folded in the folding region 320.

The amount of elastic deformation that the ribs 323 and the through-holes 321 in the folding region 320 need to have may differ depending on the curvature of radius when the display protection member 301 is folded. For example, if the radius of curvature is larger, a relatively small amount of elastic deformation may be applied to the folding region 320, and if the radius of curvature is small, a relatively large amount of elastic deformation may be applied thereto.

The flexible polymer materials may have an elastic modulus of 1 to 1000 kPa such that the folding region 320 has flexibility. If the elastic modulus exceeds 1000 kPa, the flexible polymer regions 322 have excessively high rigidity, and elastic deformation sufficient for the folding region 320 to be folded cannot occur. If the elastic modulus is below 1 kPa, the flexible polymer regions 322 have low strength, and the flexible polymer materials may thus be permanently deformed during folding or, or the flexible polymer materials may be pushed out of the through-holes 321, thereby damaging the display protection member 301.

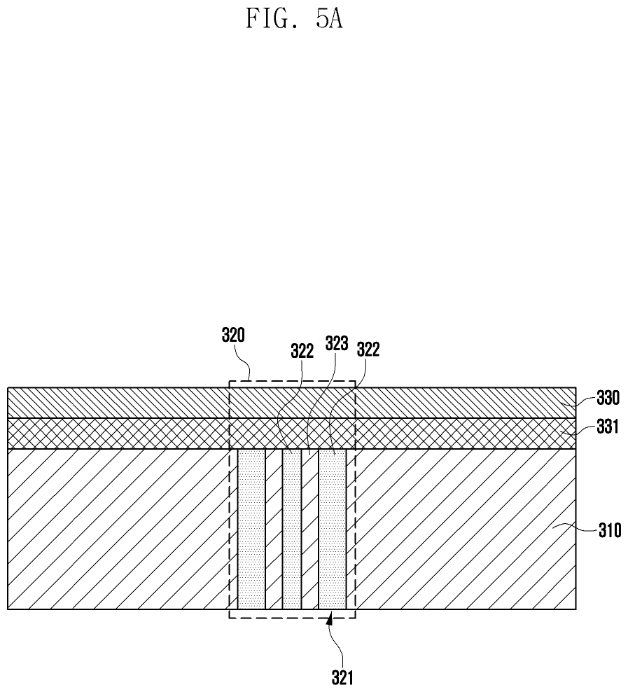

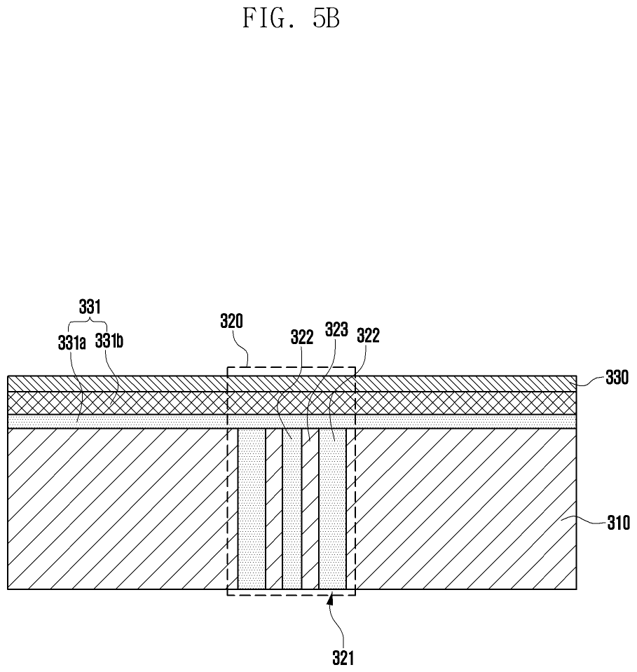

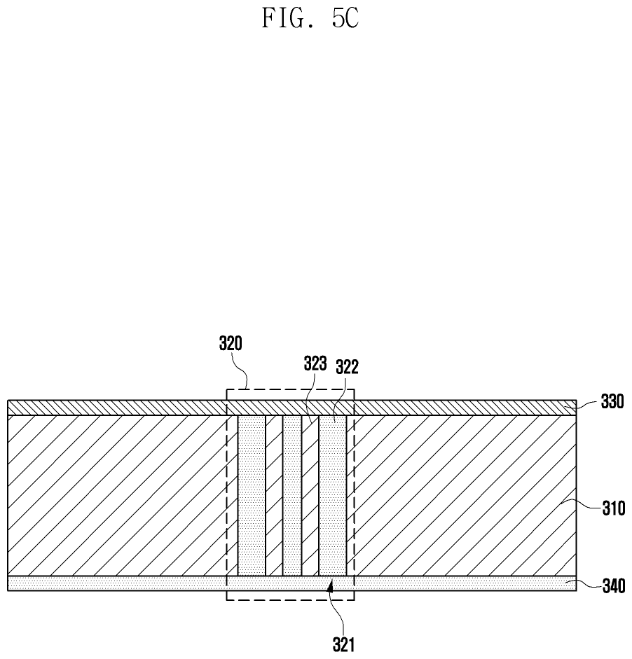

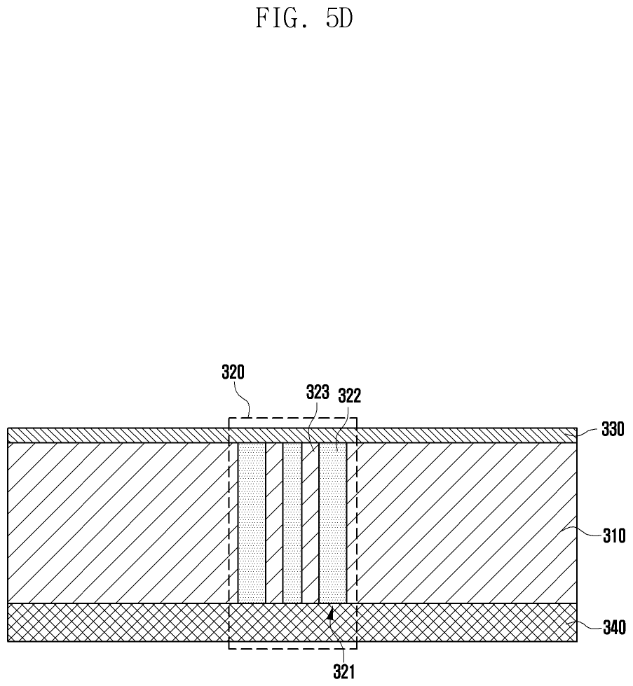

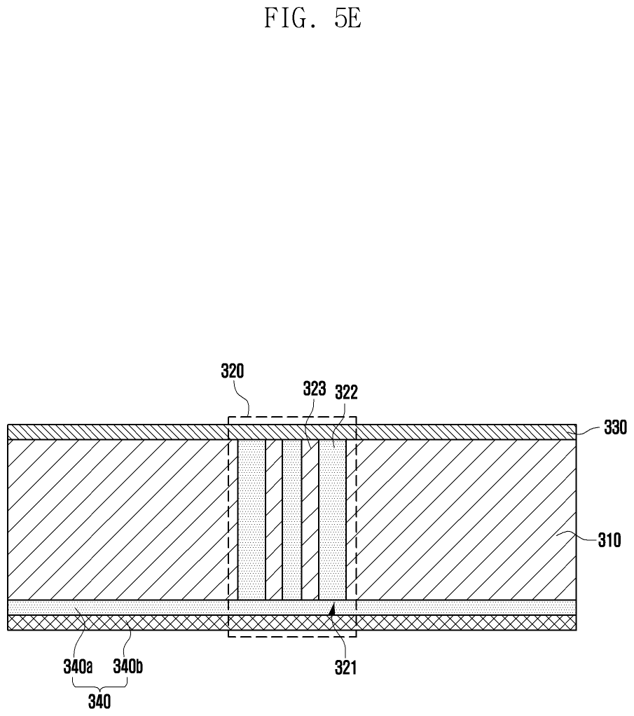

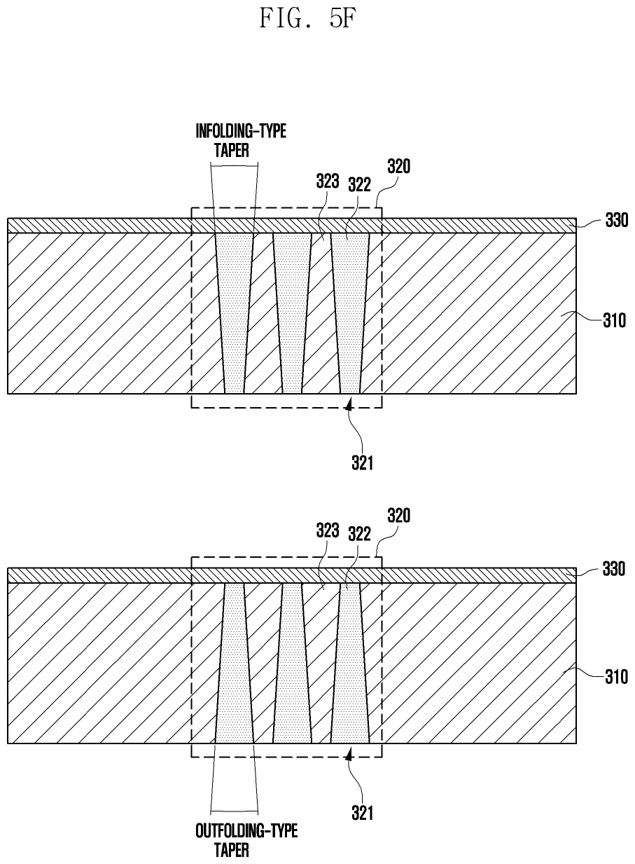

FIG. 5A is a sectional view of a display protection member 301 according to an embodiment of the disclosure.

FIG. 5B is a sectional view of a display protection member 301 according to an embodiment of the disclosure.

FIGS. 5C, 5D, and 5E are sectional views of a display protection member 301 according to various embodiments of the disclosure.

FIG. 5F is a sectional view of a display protection member 301 according to an embodiment of the disclosure.

Referring to FIGS. 5A and 5B, the display protection member 301 may include a hardness transition layer 331.

The hardness transition layer 331 may be positioned between the hard coating layer 330 and the glass layer 310, may have an elastic modulus lower than that of the hard coating layer 330 and higher than that of the flexible polymer regions 322, and may include a transparent medium-hardness polymer material. The medium-hardness polymer material may include a polymer material such as clear polyimide, polyethylene terephthalate (PET), or polypropylene (PP), for example. The ratio between hard and soft segments and/or the degree of crosslinking of the medium-hardness polymer material may be controlled such that the same has an elastic modulus lower than that of the hard coating layer 330 and higher than that of the flexible polymer regions 322. In addition, the elastic modulus of the medium-hardness polymer material may be adjusted by adding a plasticizer such as phthalates. In some embodiments, the medium-hardness polymer material may have an elastic modulus value of 10 to 1000 Mpa. However, this is exemplary, and the elastic modulus of the medium-hardness polymer material may have a value between the elastic modulus of the flexible polymer materials described above and the elastic modulus of the hard coating layer 330.

If the hard coating layer 330 is directly attached to the upper surface of the flexible polymer regions 322, pressures caused by a touch input (particularly, if a hard object such as the user's fingernail pressurizes the hard coating layer 330) and/or a stylus input may be concentrated on narrow parts of the flexible polymer regions 322. In this case, the amount of deformation of the flexible polymer regions 322 which have a low elastic modulus may be excessively large, and the hard coating layer 330 may thus fail to be supported sufficiently and then damaged. The hardness transition layer 331 may be positioned between the hard coating layer 330 and the flexible polymer regions 322 so as to support the hard coating layer 330, and may distribute pressures applied to the hard coating layer 330 during a touch input and/or a stylus input. Therefore, the risk of damage to the hard coating layer 330 during a touch input and/or a stylus input may be reduced.

Referring to FIG. 5B, in some embodiments, the hardness transition layer 331 may include a first hardness transition layer 331a which is positioned on the upper surface of the glass layer 310, and which includes a material having the same elastic modulus as that of the flexible polymer regions 322, and a second hardness transition layer 331b including a medium-hardness polymer material. In some embodiments, the first hardness transition layer 331a may be a member which extends continuously with the flexible polymer regions 322 and is integrated therewith. As the hardness transition layer 331 includes the first hardness transition layer 331a and the second hardness transition layer 331b, the elastic modulus may gradually decrease in the thickness direction from the hard coating layer 330 to the flexible polymer regions 322, thereby more effectively distributing pressures during a touch input and/or a stylus input.

In some embodiments, the hardness transition layer 331 may have an elastic modulus gradient such that the elastic modulus gradually decreases from the surface abutting the hard coating layer 330 to the surface abutting the flexible polymer regions 322. The gradual decrease in elastic modulus may be accomplished by gradually changing the degree of curing of the medium-hardness polymer material or by gradually changing the concentration of the crosslinker or plasticizer added to the medium-hardness polymer material.

Referring to FIGS. 5C, 5D, and 5E, in another embodiment, the display protection member 301 may include a repulsive force absorption layer 340 positioned on the lower surface of the glass layer 310.

The repulsive force absorption layer 340 may be positioned between the lower surface of the glass layer 310 and the panel layer of the flexible display so as to absorb a repulsive force occurring when the flexible display panel is folded or unfolded. During an operation of folding or unfolding the flexible display and the display protection member 301, a repulsive force caused by elasticity of the display protection member 301 may be applied to the panel layer, thereby damaging the panel layer. The repulsive force absorption layer 340 may absorb the above-described elastic repulsive force, thereby reducing the risk of damage to the panel layer.

Referring to FIG. 5C, the repulsive force absorption layer 340 may include a first repulsive force absorption layer 340a including a material having substantially the same elastic modulus as that of the flexible polymer regions 322. In some embodiments, the repulsive force absorption layer 340 may be an integrated member extending from the flexible polymer regions 322. Referring to FIG. 5D, the repulsive force absorption layer 340 may include a second repulsive force absorption layer 340b including a material having a higher elastic modulus than the flexible polymer regions 322. For example, the second repulsive force absorption layer 340b may include the same material as the medium-hardness polymer material included in the hardness transition layer 331 described above.

Referring to FIG. 5E, the repulsive force absorption layer 340 may include flexible repulsive force absorption layer 340 positioned on the lower portion of the glass layer 310 and a medium-hardness repulsive force absorption layer 340 positioned on the lower portion of the flexible repulsive force absorption layer 340. As the elastic modulus of the repulsive force absorption layer 340 gradually increases toward the panel positioned on the lower portion of the display protection member 301, repulsive forces generated by folding or unfolding the display protection member 301 may be distributed, thereby improving the panel protection capability.

Referring to FIG. 5F, the through-holes 321 and the flexible polymer regions 322 may have a tapered shape. The tapered shape may refer to an infolding-type taper configured such that the width of the through-holes 321 gradually increases from the glass layer 310 to the upper side, or an outfolding-type taper configured such that the width of the through-holes 321 gradually decreases from the glass layer 310 to the upper side. In the case of the infolding-type taper, the width of the through-holes 321 increases upwards, thereby securing spaces for elastic deformation of the glass, such that, when the display protection member 301 is folded in the infolding type, a high degree of flexibility may be given to the glass layer 310. In the case of the outfolding-type taper, the width of the through-holes 321 increases downwards, thereby securing spaces for elastic deformation, such that, when the display protection member 301 is folded in the outfolding type, a high degree of flexibility may be given to the glass layer 310. Therefore, the folding direction of the foldable electronic device (for example, the electronic device in FIGS. 2A to 2F) may be substantially identical to the direction in which the display protection member 301 is folded.

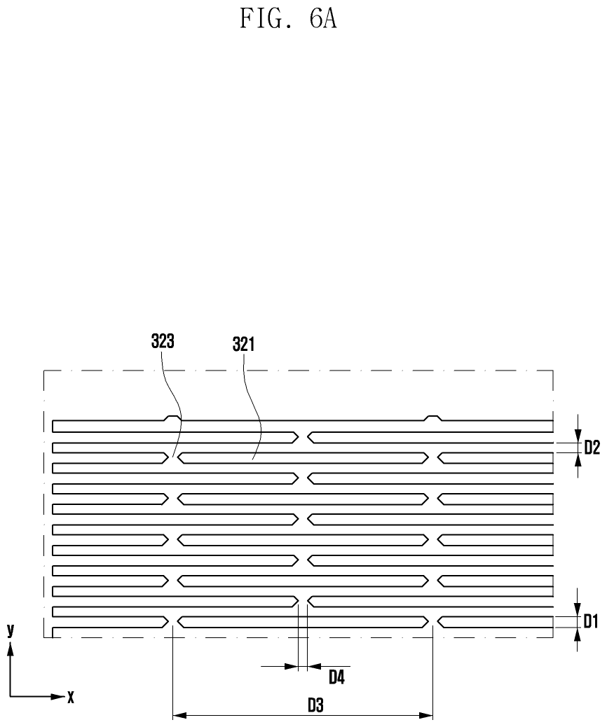

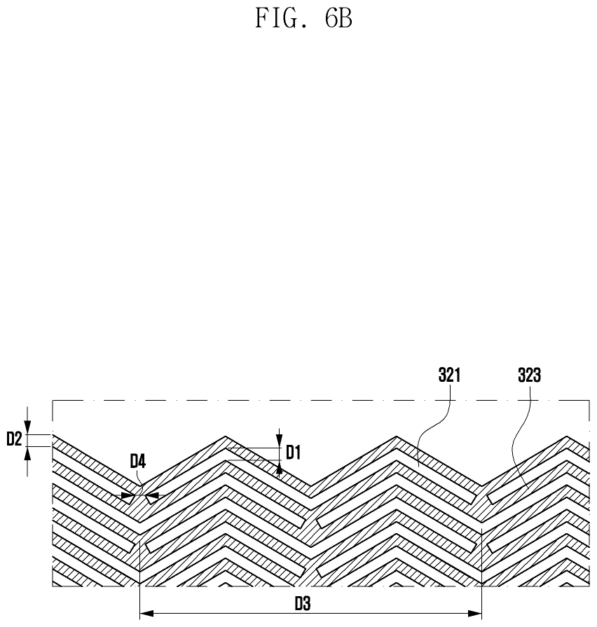

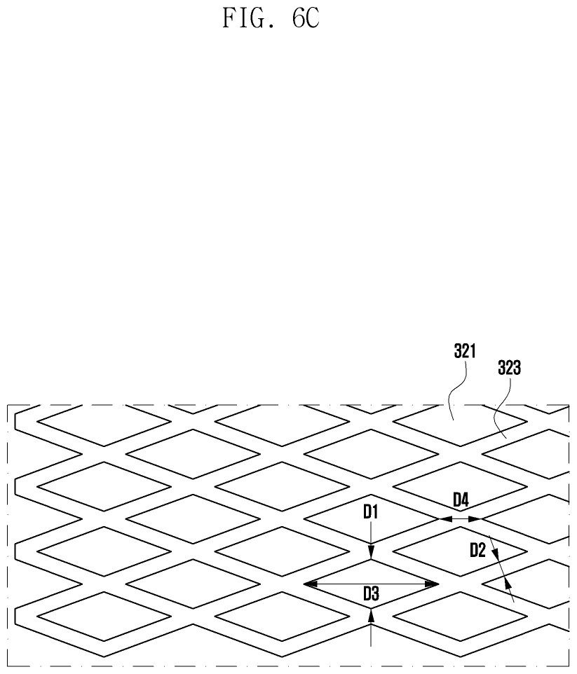

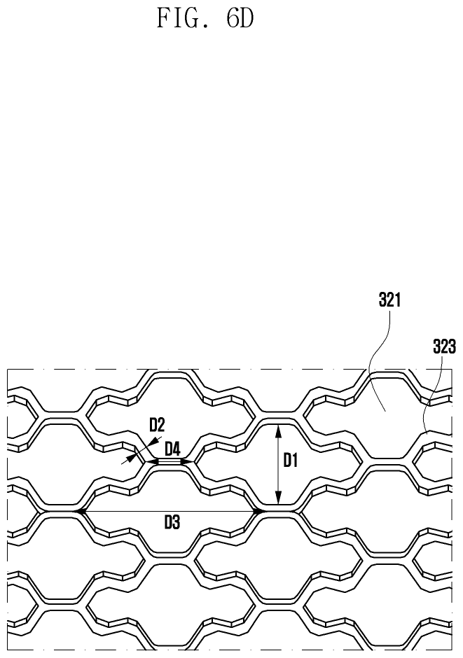

FIGS. 6A, 6B, 6C, and 6D are magnified plan views illustrating the shape of through-holes 321 according to various embodiments of the disclosure.

Referring to FIGS. 6A and 6B, dimensions of the folding region 320, such as the width of the through-holes 321, the width of the ribs 323, the length of the through-holes 321, and the length of the ribs 323, may be determined according to the design of the foldable electronic device. As the width D1 of the through-holes 321 and the width D2 of the ribs 323 decrease, the flexibility of the folding region 320 may increase, and the elastic repulsive force may decrease. In addition, as the length D3 of the through-holes 321 increases, the flexibility of the folding region 320 may increase, and as the length D4 of the ribs 323 decreases, the flexibility of the folding region 320 may increase.

In some embodiments, if the foldable electronic device is designed such that the folding region 320 is folded at a large radius of curvature, for example, in the case of an outfolding-type foldable electronic device, the amount of elastic deformation that the folding region 320 needs to have is relatively small, and the through-holes 321 and the ribs 323 of the folding region 320 may be configured to have large widths. In other embodiments, if the foldable electronic device is designed such that the folding region 320 is folded at a small radius of curvature, for example, in the case of an infolding-type foldable electronic device, the amount of elastic deformation that the folding region 320 needs to have is relatively large, and the through-holes 321 and the ribs 323 of the folding region 320 may be configured to have small widths.

Referring to FIG. 6A, in some embodiments, the through-holes 321 may have slit shapes. The through-holes 321 in slit shapes may extend in the longitudinal direction, that is, in a direction parallel to the folding axis (in the direction of x-axis in FIG. 6A), and facing inner surfaces of the through-holes 321 may be substantially parallel to each other. Referring to FIG. 6B, the through-holes 321 may have wave shapes. The through-holes 321 in wave shapes may be obtained by bending the slit-shaped through-holes 321 with regard to the width direction, that is, the direction perpendicular to the folding axis on the surface of the glass layer 310. The wave shapes have higher flexibility than the slit shapes and, referring to FIG. 6C, in some embodiments, the through-holes 321 may have rhombus shapes. The rhombus shapes are advantageous in that the width D1 of the through-holes 321 may be made larger than the width D2 of the ribs 323. Referring to FIG. 6D, in some embodiments, the through-holes 321 may have the overall shape of rhombuses while being wavy in the width direction. The wavy shapes advantageously prevent concentration of stress on specific parts of the ribs 323.

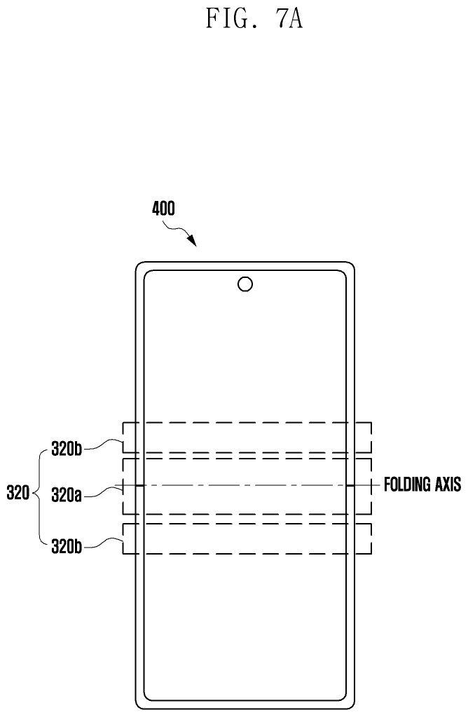

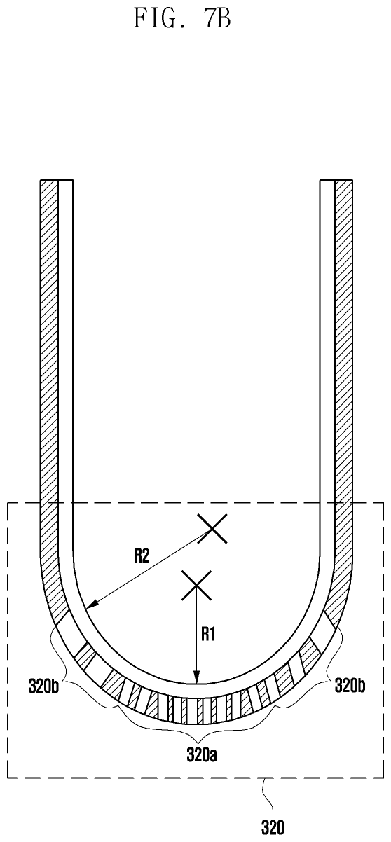

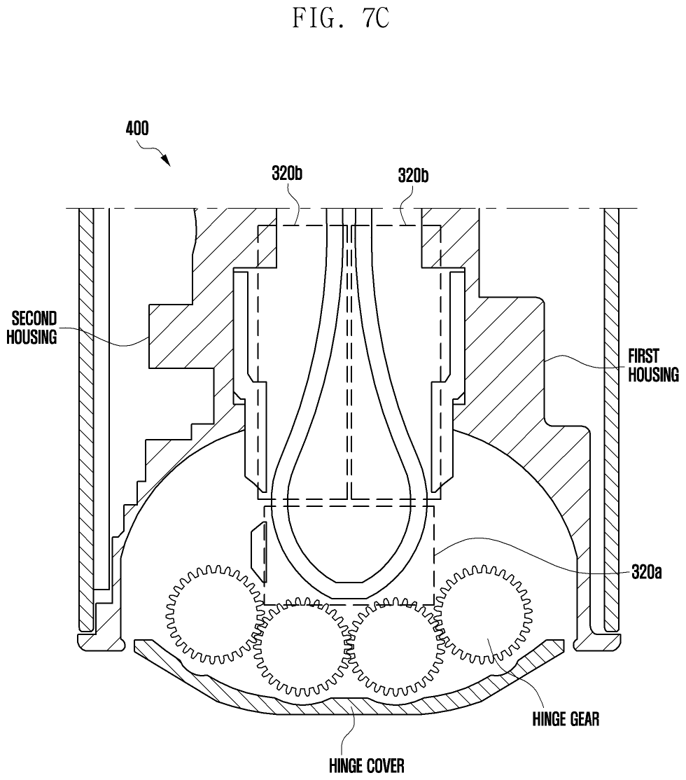

FIG. 7A is a plan view of a foldable electronic device 400 according to an embodiment of the disclosure.

FIG. 7B is a side sectional view of a display protection member 301 of a foldable electronic device 400 according to an embodiment of the disclosure.

FIG. 7C is a magnified sectional view of a hinge portion of a foldable electronic device 400 according to an embodiment of the disclosure.

Referring to FIGS. 7A and 7B, the folding region 320 of the display protection member 301 may include a first folding region 320a and a second folding region 320b. The first folding region 320a may be positioned on the center portion of the folding area of the foldable electronic device 400, and the second folding region 320b may be positioned on the peripheral portion of the first folding region 320a around the folding axis of the foldable electronic device 400.

Referring to FIG. 7B, when the foldable electronic device 400 is folded, the radius of curvature R1 of the first folding region 320a may be smaller than the radius of curvature R2 of the second folding region 320b. For example, the folding region 320 may be folded along a curve which is not an arc, for example, along an elliptical curve, a parabolic curve, a hyperbolic curve, or a curve extending in the vertical direction (y-direction in FIG. 7B) similar thereto. When the folding region 320 is folded along the above-described curve, the thickness of the foldable electronic device 400 in the folded state may be reduced.

In order to reduce the thickness of the foldable electronic device 400 in the folded state, the radius of curvature of the folding region 320 is preferably reduced. However, if the radius of curvature is reduced, the area of the folding region 32 is reduced, and the bending moment applied by folding may be concentrated on a narrow portion of the folding region 320, thereby damaging the display protection member 301. As the folding region 320 includes a first folding region 320a which is folded at a relatively small radius of curvature R1 and a second folding region 320b which is folded at a relatively large radius of curvature, a part of bending moment applied to the first folding region 320a may be distributed to the second folding region 320b, thereby reducing the risk of damage to the display protection member 301.

In order for the second folding region 320b to be folded at a larger radius of curvature than the first folding region 320a, and width of through-holes 321 and/or the width of ribs 32b of the second folding region 320b may be larger than those of the first folding region 320a. The influence of the width of the through-holes 321 and/or the ribs 323 on the radius of curvature at which the folding region 320 is folded is as described above.

Referring to FIG. 7C, in another embodiment, the foldable electronic device 400 may include a first folding region 320a which is folded in when the folding region 320 is folded, and a second folding region 320b which is folded out. The folding configuration in which the region of the folding region 320 adjacent to the folding axis is folded in, and the peripheral portion thereof is folded out, may be referred to as waterdrop-shaped folding. The first folding region 320a may be configured appropriately for infolding, for example, such that the width of the through-holes 321 and/or the ribs 323 is relatively small, and the second folding region 320b may be configured appropriately for outfolding, for example, such that the width of the through-holes 321 and/or the ribs 323 is relatively large. In addition, the tapering direction of the through-holes 321 in the first folding region 320a may be opposite to that of the through-holes 321 in the second folding region 320b. For example, the through-holes 321 in the first folding region 320a may have an infolding-type taper, and the through-holes 321 in the second folding region 320b may have an outfolding-type taper. During waterdrop-shaped folding, end portions of the second folding region 320b may be adjacent to or abut each other. Therefore, the thickness of the foldable electronic device 400 may be reduced in the folded state.

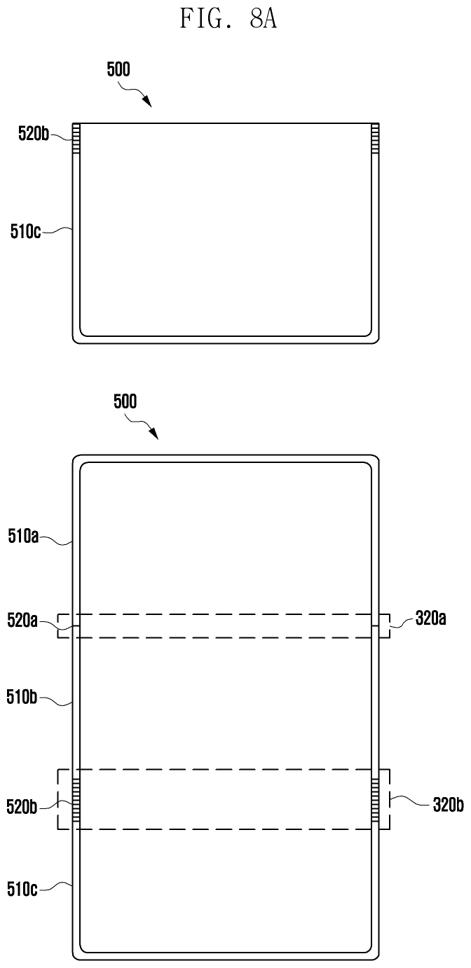

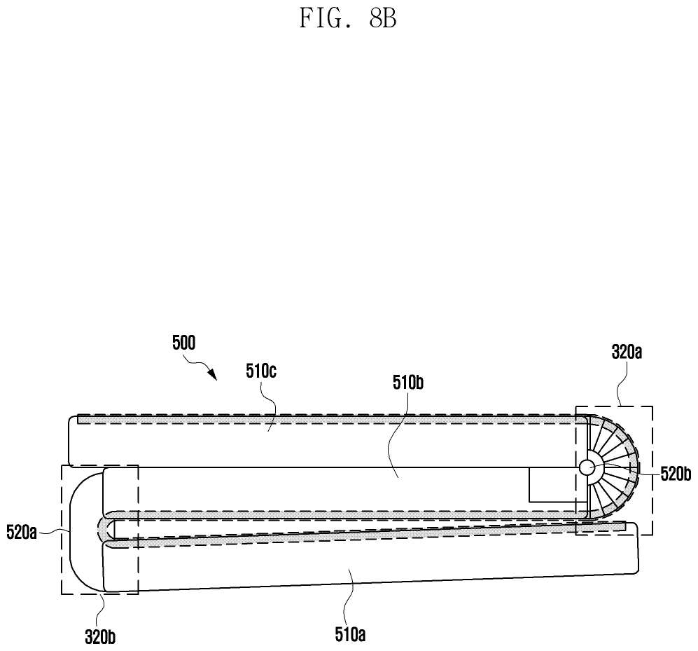

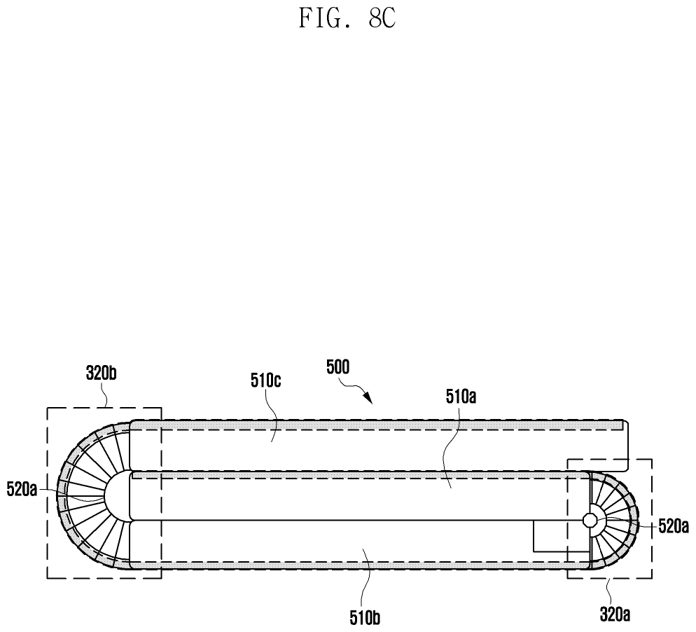

FIG. 8A is a plan view illustrating a foldable electronic device 500 in an unfolded state and in a folded state according to an embodiment of the disclosure.

FIG. 8B is a side view of a foldable electronic device 500 in a folded state according to an embodiment of the disclosure.

FIG. 8C is a side view of a foldable electronic device 500 in a folded state according to an embodiment of the disclosure.

Referring to FIG. 8A, the electronic device according to some embodiments may include multiple housings (for example, a first housing 510a, a second housing 510b, and a third housing 510c) and multiple hinge portions (for example, a first hinge portion 520a and a second hinge portion 520b) configured to connect the multiple housings rotatably or foldably. Although FIG. 8A illustrates an electronic device including three housings and two hinge portions, this is ˜˜, and it would be obvious to those skilled in the art that the number of housings and hinge portions is variable. The foldable electronic device 500 including multiple hinge portions may be referred to as a multi-foldable electronic device. The display protection member 301 of the foldable electronic device 500 may include multiple folding regions 320 (for example, a first folding region 320a and a second folding region 320b).

Referring to FIG. 8B, the first folding region 320a of the electronic device according to some embodiments may be folded in, and the second folding region 320b thereof may be folded out. Such a folding configuration may be referred to as Z-type folding. The width of through-holes 321 and/or the width of ribs 323 in the first folding region 320a may be configured relatively small such that the first folding region 320a has a small radius of curvature for infolding, and the width of through-holes 321 and/or the width of ribs 323 in the second folding region 320b may be configured relatively large such that the second folding region 320b has a large radius of curvature for outfolding, In addition, the through-holes 321 in the first folding region 320a may have a infolding-type taper, and the through-holes 321 in the second folding region 320b may have an outfolding-type taper.

Referring to FIG. 8C, the electronic device according to other embodiments may be configured such that the first folding region 320a and the second folding region 320b are folded in, and the first housing 510a is folded to be positioned between the second housing 510b and the third housing 510c. Such a folding configuration may be referred to as G-type folding. The first housing 510 may be folded out to be positioned between the second housing 510b and the third housing 510c such that multiple housings are tightly folded. Therefore, the G-type folded foldable electronic device 500 may have a reduced thickness in the folded state compared with the Z-type folded foldable electronic device 500 illustrated in FIG. 8B.

The first folding region 320a may have a smaller radius of curvature than the second folding region 320b. Therefore, the width of the through-holes 321 and/or the width of the ribs 323 in the first folding region 320a may be configured smaller than those in the second folding region 320b. Therefore, the foldable electronic device 500 may be designed such that the flexibility and protection capability of the display protection member 301 are optimized in each folding region 320.

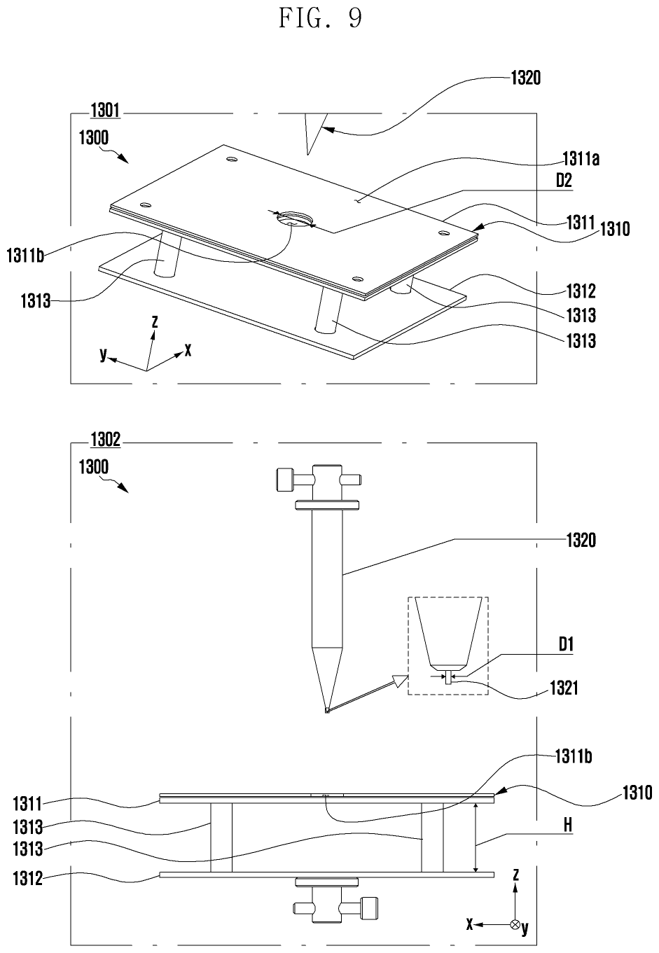

FIG. 9 is a perspective view 1301 of a test device 1300 for first evaluation, second evaluation, and third evaluation, together with a view 1302 of the test device 1300 according to an embodiment of the disclosure.

Referring to FIG. 9, in an embodiment, the test device 1300 may include a clamping device (for example, manual clamping fixture) 1310 and a probe (for example, a penetration probe) 1320. A flexible material (for example, flexible films and/or laminates) (for example, the glass layer 310 in FIGS. 3A to 3C, or a laminate including the glass layer 310) may be disposed on the clamping device 1310. The probe 1320 may be implemented to be able to move straight with regard to the clamping device 1310. The probe 1320 may move straight so as to apply a load to the flexible material disposed on the clamping device 1310. When the probe 1320 fractures the flexible material, the load (for example, fracture load) may be detected through a detector (for example, a sensor) connected to the probe 1320.

According to an embodiment, the clamping device 1310 may include a first plate 1311, a second plate 1312, and multiple support portions 1313.

According to an embodiment, the first plate 1311 may be a surface plate. The flexible material to be tested (for example, the glass layer 310 in FIGS. 3A to 3C, or a laminate including the glass layer 310) may be disposed on the first plate 1311. The first plate 1311 may include a support surface 1311a on which the flexible material to be tested is disposed. The support surface 1311a of the first plate 1311 may be substantially planar. The first plate 1311 may include an opening 1311b corresponding to the probe 1320. The opening 1311b may reduce or prevent the influence of the first plate 1311 on flexible material strength detection. The opening 1311b may be configured such that the first plate 1311 does not interfere with straight movements of the probe 1320.

According to an embodiment, the second plate 1312 may be spaced apart from the first plate 1311 in the direction in which the probe 1320 moves straight so as to pressurize the flexible material (for example, the glass layer 310 in FIGS. 3A to 3C, or a laminate including the glass layer 310). The space between the first plate 1311 and the second plate 1312 may be configured such that the clamping device 1310 does not interfere with straight movements of the probe 1320. The multiple support portions 1313 may be disposed between the first plate 1311 and the second plate 1312. The multiple support portions 1313 may connect the first plate 1311 and the second plate 1312. The second plate 1312 may be coupled to the body (not illustrated separately) included in the test device 1300, and the first plate 1311 may be supported by the multiple support portions 1313 and spaced apart from the second plate 1312 coupled to the body. The body of the test device 1300 may be the substantial support body configured to stably support components such as the probe 1320 and the second plate 1312, thereby reducing vibration or shaking when the test device 1300 is driven.

According to an embodiment, the glass layer 310 in FIGS. 3A to 3C, or a laminate (for example, the display protection member 301 in FIGS. 3A to 3C) including the glass layer 310 may be disposed on the support surface 1311a of the first plate 1311. According to an embodiment, the probe 1320 may include a pen input device (for example, an electronic pen, a digital pen, or a stylus pen). The pen input device may be disposed on the test device 1300 while being erected substantially perpendicularly to the support surface 1311a of the first plate 1311. When the test device 1300 is driven, the pen tip 1321 of the pen input device may pressurize the glass layer 310 (refer to FIGS. 3A to 3C) disposed on the first plate 1311. In the test device 1300, a movement of the vertically erected pen input device so as to apply a load to the glass layer 310 (refer to FIGS. 3A to 3C) may be understood as being at least similar to a situation in which the user dropped the pen input device, or a situation in which the user makes a touch input by using the pen input device.

According to an embodiment, the pen input device may substantially have a weight of about 5.6 g.

According to an embodiment, the diameter D1 of the pen tip 1321 included in the pen input device may substantially be about 0.3 mm.

According to an embodiment, the pen tip 1321 of the pen input device may be a ball tip made of tungsten carbide. The ball tip may have an end provided in a convexly curved shape.

According to various embodiments, the probe 1320 may be provided as an object that can substantially replace the pen input device.

According to an embodiment, the test device 1300 may follow ASTM F1306-16 standards for evaluating the penetration resistance of flexible materials, in connection with third evaluation. The probe 1320 may be provided in conformity with ASTM F1306-16 standards. According to ASTM F1306-16 standards, the support surface 1311a of the first plate 1311 may substantially have a surface roughness of about 200. According to ASTM F1306-16 standards, the diameter D2 of the opening 1311b of the first plate 1311 may substantially be about 35 mm. According to ASTM F1306-16 standards, the distance H at which the first plate 1311 and the second plate 1312 are spaced apart in the direction of straight movement of the probe 1320 may substantially be about 76 mm.

According to an embodiment, first evaluation and second evaluation may be performed through the test device 1300 according to ASTM F1306-16 standards.

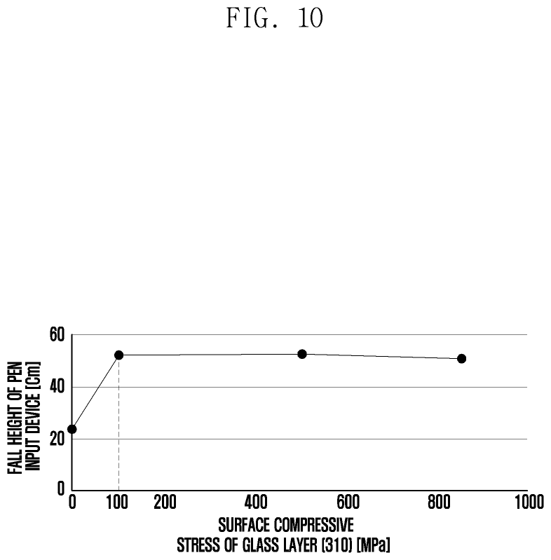

FIG. 10 is a graph illustrating the minimum surface compressive stress which the glass layer 310 (refer to FIGS. 3A to 3C) is to have so as to cause substantially no damage to the glass layer 310, in terms of the fall height of the pen input device, according to an embodiment of the disclosure.

Referring to FIG. 10, in an embodiment, the glass layer 310 may substantially have a thickness of about 0.14 mm or less than 0.14 mm. In order to reduce or prevent damage to the glass layer 310 caused by an impact from the falling pen input device, the glass layer 310 may be implemented to have a compressive strength sufficient to endure a surface compressive stress of about 100 MPa or above 100 MPa.

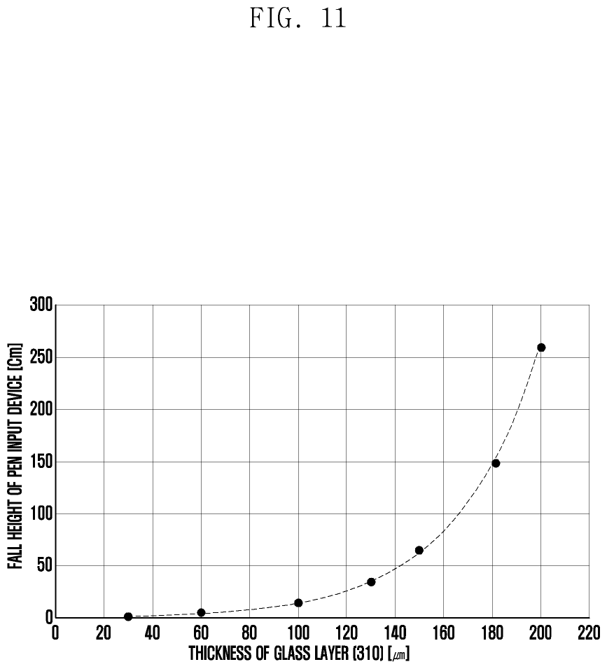

FIG. 11 is a graph illustrating the fall height of the pen input device at which the glass layer 310 is damaged, in terms of the thickness of the glass layer 310, as first evaluation of a laminate including the glass layer 310 in FIGS. 3A to 3C, according to an embodiment of the disclosure.

According to an embodiment, the laminate including the glass layer 310 in FIGS. 3A to 3C may include a glass layer 310, a flexible display (for example, the display 299 in FIG. 2F), and an adhesive material (for example, the repulsive force absorption layer 340 in FIG. 5C) between the glass layer 310 and the flexible display.

Referring to FIG. 11, the fall height of the pen input device at which the glass layer 310 is damaged may increase in proportion to the thickness of the glass layer 310 (refer to FIGS. 3A to 3C) included in the laminate. In an embodiment, the thickness of the glass layer 310 may be limited to a value determined such that, when the electronic device (for example, the electronic device 200 in FIG. 2A) transitions from an unfolded state to a folded state, the same can bend while reducing bending stress without damage. In an embodiment, the thickness of the glass layer 310 may be limited to a value determined such that the curvature or the radius of curvature can be reduced as much as possible without damage (or while reducing bending stress) during bending.

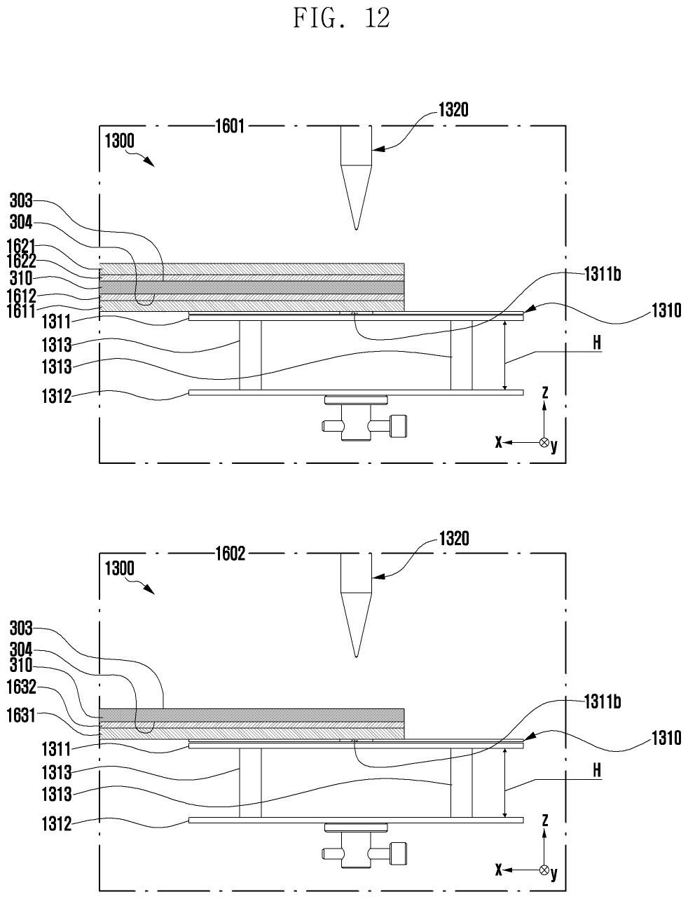

FIG. 12 is a view 1601 of a test device 1300 and a glass layer 310 in relation to first evaluation, together with a view 1602 of the test device 1300 and the glass layer 310 in relation to second evaluation, according to an embodiment of the disclosure.

Referring to FIG. 12, in connection with first evaluation through the test device 1300, a first protection film 1611 of polymer may be disposed (for example, attached) on one surface 303 of the glass layer 310 through a first adhesive material (or a first attachment material) 1612. In connection with first evaluation through the test device 1300, a second protection film 1621 of polymer may be disposed (for example, attached) on the other surface 304 of the glass layer 310 through a second adhesive material (or a second attachment material) 1622. The first protection film 1611 and the second protection film 1621 may substantially be polyethylene terephthalate (PET) having a thickness of about 50 μm, for example. The first adhesive material 1612 and the second adhesive material 1622 may substantially be pressure sensitive adhesive (PSA) having a thickness of about 25 μm or less than 25 μm, for example.

According to an embodiment, in connection with second evaluation through the test device 1300, a protection film 1631 of polymer may be disposed (for example, attached) on the lower surface 304 of the glass layer 310 through an adhesive material (or an attachment material) 1632. The protection film 1631 may substantially be PET having a thickness of about 200 μm, for example. The adhesive material 1632 may be PSA having a thickness of about 10 μm or less than 10 μm, for example. In an embodiment, in connection with second evaluation through the test device 1300, a protection film having hardness Hs30 (for example, a urethane jig) (not illustrated separately) may be positioned to cover the lower surface 304 of the glass layer 310.

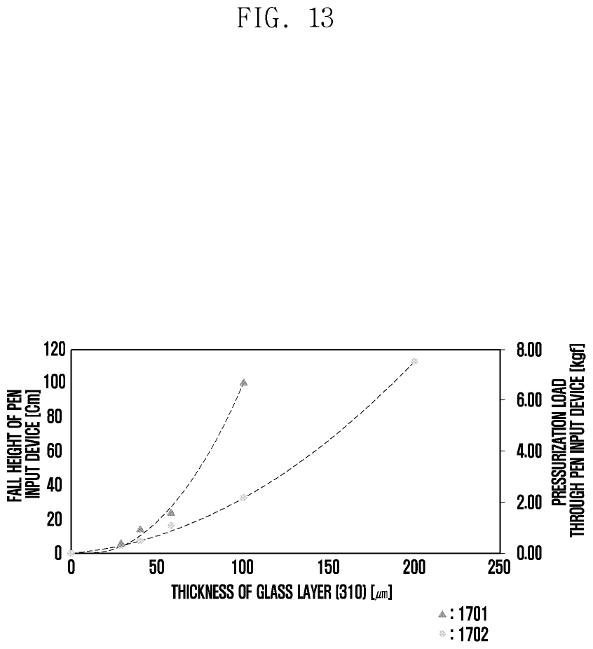

FIG. 13 is a graph 1701 illustrating the fall height of a pen input device (for example, the probe 1320 in FIG. 16) at which the glass layer 310 (refer to FIGS. 3A to 3C) is damaged, in terms of the thickness of the glass layer 310, as a result of first evaluation through the test device 1300 (refer to FIG. 9), together with a graph 1702 illustrating the pressurization load through the pen input device by which the glass layer 310 is damaged, in terms of the thickness of the glass layer 310, as a result of second evaluation through the test device 1300 according to an embodiment of the disclosure.

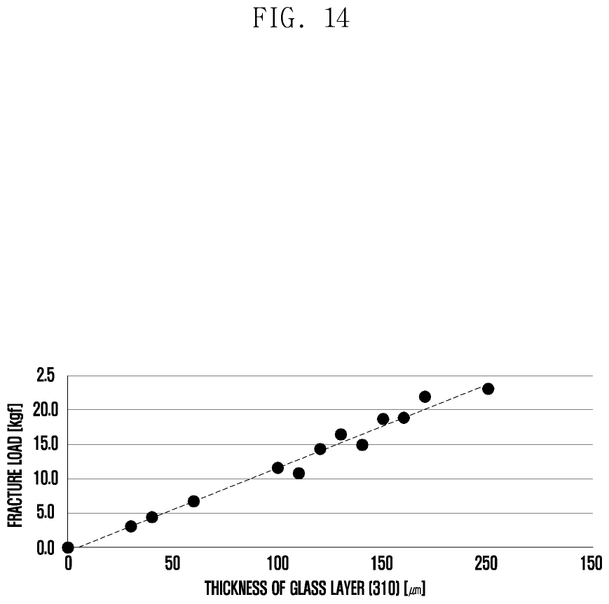

FIG. 14 is a graph illustrating a fracture load in terms of the thickness of the glass layer 310 (refer to FIGS. 3A to 3C) as the result of third evaluation (for example, penetration resistance evaluation according to ASTM F1306-16 standards) through the test device 1300 (refer to FIG. 9) according to an embodiment of the disclosure.

According to an embodiment, in view of the first evaluation result illustrated in FIG. 13, the glass layer 310 may be implemented such that the fall height of the pen input device, at which the glass layer 310 (refer to FIGS. 3A to 3C) may be damaged, is about 6 cm or larger than 6 cm.

According to an embodiment, in view of the second evaluation result illustrated in FIG. 13, the glass layer 310 may be implemented such that the pressurization load through the pen input device, by which the glass layer 310 may be damaged, is about 0.3 kgf or above 0.3 kgf.

According to an embodiment, in view of the third evaluation result illustrated in FIG. 14, the glass layer 310 may be implemented such that the penetration resistance (for example, fracture load or fracture strength) is about 3 kgf or larger than 3 kgf.

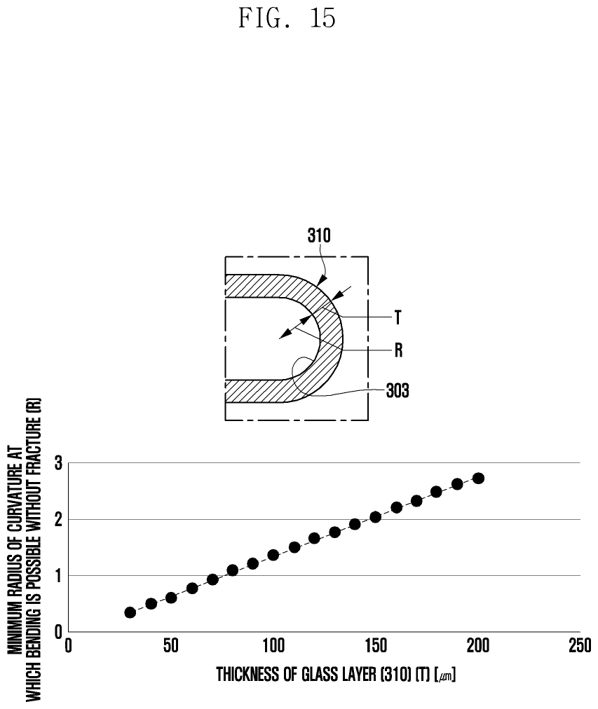

FIG. 15 is a sectional view of the glass layer 310 in a folded state of the electronic device 1 (refer to FIG. 1), together with a graph illustrating the minimum radius of curvature R at which the glass layer 310 may bend without fracture, in terms of the thickness T of the glass layer 310 according to an embodiment of the disclosure.

Referring to FIG. 15, bending stress may occur in the bending region of the glass layer 310 as a result of collision between an increasing force (for example, tensile stress) on one surface of the bending region and a decreasing force (for example, compressive stress) on the other surface of the bending region. The bending stress occurring in the bending region of the glass layer 310 may be proportional to the thickness T of the glass layer 310 and inversely proportional to the radius of curvature R. The radius of curvature R may be substantially based on the inner surface 303 during bending of the glass layer 310. In an embodiment, the thickness T of the glass layer 310 may be determined such that the glass layer 310 can have a minimum radius of curvature R of about 5 mm, or larger than 0 mm and smaller than 5 mm, at which the glass layer 310 can bend without fracture.

Embodiments disclosed herein and illustrated in the drawings are only specific examples presented to easily describe technical content according to embodiments disclosed herein and to help understanding of embodiments disclosed herein, and are not intended to limit the scope of embodiments disclosed herein. Therefore, the scope of various embodiments disclosed herein is to be interpreted as encompassing not only embodiments disclosed herein, but also all changed or modified forms derived based on the technical idea of various embodiments disclosed herein.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A foldable electronic device comprising:
a foldable housing comprising multiple housings and at least one hinge configured to rotatably couple the multiple housings, the folding housing being folded around the hinge; and
a flexible display disposed on the foldable housing so as to be folded according to a folding operation of the foldable housing,
wherein the flexible display comprises:
a panel layer configured to display image information,
a glass layer positioned above the panel layer with reference to a direction in which the image information is displayed, the glass layer being folded when the flexible display is folded,
a folding region positioned on a folding part of the glass layer, the folding region comprising multiple through-holes formed to penetrate the glass layer in a thickness direction and arranged regularly on a surface of the glass layer, and a rib which is a region between the multiple through-holes adjacent to each other,
a flexible polymer region comprising a transparent and elastic flexible polymer material positioned in the through-holes, and
a hard coating layer positioned on upper surfaces of the glass layer and the flexible polymer region, the hard coating layer having a higher elastic modulus than the transparent and elastic flexible polymer material.

2. The foldable electronic device of claim 1,
wherein the transparent and elastic flexible polymer material has an elastic modulus of 1 to 1000 kPa, and
wherein the hard coating layer has an elastic modulus of 1 to 10 Gpa.

3. The foldable electronic device of claim 1, further comprising:
a hardness transition layer positioned below the hard coating layer and above the glass layer, the hardness transition layer comprising a medium-hardness polymer material having an elastic modulus higher than the transparent and elastic flexible polymer material and lower than the hard coating layer,
wherein the hardness transition layer comprises:
a first hardness transition layer comprising a material having a same elastic modulus as the transparent and elastic flexible polymer material, and
a second hardness transition layer comprising the medium-hardness polymer material.

4. The foldable electronic device of claim 1, further comprising:
a repulsive force absorption layer positioned below the glass layer,
wherein the repulsive force absorption layer comprises:
a first repulsive force absorption layer, and
a second repulsive force absorption layer having a higher elastic modulus than the first repulsive force absorption layer.

5. The foldable electronic device of claim 1, wherein the through-holes comprise at least one of slit shapes extending in a direction parallel to a folding axis of the foldable electronic device, or rhombus shapes having diagonal lines arranged parallel to the folding axis on a surface of the glass layer.

6. The foldable electronic device of claim 1, wherein the folding region comprises a rib which is a region between the multiple through-holes adjacent to each other, and the rib comprises a wave shape bent in a direction perpendicular to a folding axis on a surface of the glass layer.

7. The foldable electronic device of claim 1, wherein the through-holes comprise taper shapes such that a width of the through-holes changes gradually along the thickness direction of the glass layer.

8. The foldable electronic device of claim 1,
wherein the folding region comprises:
a first folding region which is a region adjacent to a folding axis of the foldable electronic device, and
a second folding region positioned on a peripheral portion of the first folding region around the folding axis of the foldable electronic device,
wherein, when the foldable electronic device is folded, a radius of curvature of the first folding region is larger than a radius of curvature of the second folding region, and
wherein a width of at least one of the through-holes or the rib in the first folding region is small compared with the second folding region.

9. The foldable electronic device of claim 1,
wherein the folding region comprises:
a first folding region which is a region adjacent to a folding axis of the foldable electronic device, and
a second folding region positioned on a peripheral portion of the first folding region around the folding axis of the foldable electronic device,
wherein the first folding region is folded in, when the foldable electronic device is folded, such that an upper end portion of the glass layer is positioned inside a curved shape formed by folding of the first folding region,
wherein the second folding region is folded out such that the upper end portion of the glass layer is positioned outside a curved shape formed in the second folding region, and
wherein a width of at least one of the through-holes or the rib in the first folding region is small compared with the second folding region.

10. The foldable electronic device of claim 9,
wherein the through-holes comprise a taper such that the width of the through-holes changes gradually along the thickness direction of the glass layer, and
wherein the through-holes in the first folding region and the second folding region have tapers in opposite directions.

11. The foldable electronic device of claim 1,
wherein the foldable housing comprises a first housing, a second housing, a third housing, a first hinge portion configured to foldably connect the first housing and the second housing, and a second hinge portion configured to foldably connect the second housing and the third housing,
wherein the folding region comprises a first folding region positioned in a region of the glass layer corresponding to the first hinge portion, and a second folding region positioned in a region of the glass layer corresponding to the second hinge portion,
wherein the first folding region is folded in, when the foldable electronic device is folded, such that an upper end portion of the glass layer is positioned inside a curved shape formed by folding of the first folding region, and
wherein the second folding region is folded out such that the upper end portion of the glass layer is positioned outside a curved shape formed in the second folding region.

12. The foldable electronic device of claim 1,
wherein the foldable housing comprises a first housing, a second housing, a third housing, a first hinge portion configured to foldably connect the first housing and the second housing, and a second hinge portion configured to foldably connect the second housing and the third housing,
wherein the folding region comprises a first folding region positioned in a region of the glass layer corresponding to the first hinge portion, and a second folding region positioned in a region of the glass layer corresponding to the second hinge portion, and
wherein, when the foldable electronic device is folded, a radius of curvature of the second folding region is larger than a radius of curvature of the first folding region, and the first housing is folded to be positioned between the second housing and the third housing.

13. The foldable electronic device of claim 1, wherein the glass layer has a fracture strength of 3 kgf or above 3 kgf and a surface compressive strength of 100 MPa or above 100 MPa, based on ASTM F1306-16 standards.

14. The foldable electronic device of claim 1,
wherein the glass layer has a strength determined such that, when a pen input device comprising a pen tip of a 0.3 mm diameter and having a weight of 5.6 g fall vertically to the surface of the glass layer,
wherein the glass layer is not damaged in case that a fall height of the pen input device is 6 cm or above 6 cm, and
wherein, when the pen input device is pressurized against the surface of the glass layer, the glass layer is not damaged in case that a pressurization load of the pen input device is 0.3 kgf or above 0.3 kgf.

15. The foldable electronic device of claim 1, wherein the glass layer is configured to bend without fracture at a radius of curvature of 5 mm or a radius of curvature larger than 0 mm and smaller than 5 mm.

16. The foldable electronic device of claim 1, further comprising:
a display protection member positioned on an upper portion of the glass layer; and
a plurality of ribs between neighboring through-holes of the multiple through-holes.

17. The foldable electronic device of claim 16, wherein a width of the multiple through holes decreases as the plurality of ribs are deformed by a compressive stress in an inner area when the display protection member is folded.

18. The foldable electronic device of claim 16, wherein a width of the multiple through holes increases as the plurality of ribs are deformed by a tensile stress in an outer area.
